(19) United States
(12) Patent Application Publication
(10) Pub. No.: US 2024/0203929 A1
(43) Pub. Date: Jun. 20, 2024

(54) SEMICONDUCTOR MODULE

(71) Applicant: FUJI ELECTRIC CO., LTD., Kawasaki-shi (JP)

(72) Inventors: Yushi SATO, Kawasaki-shi (JP); Kazuo ENOMOTO, Kawasaki-shi (JP)

(73) Assignee: FUJI ELECTRIC CO., LTD., Kawasaki-shi (JP)

(21) Appl. No.: 18/592,387

(22) Filed: Feb. 29, 2024

Related U.S. Application Data
(63) Continuation of application No. PCT/JP2023/008465, filed on Mar. 7, 2023.

(30) Foreign Application Priority Data
Mar. 28, 2022 (JP) 2022-051039

(51) Int. Cl. H01L 23/00; H01L 23/31; H01L 25/07

(52) U.S. Cl. CPC H01L 24/37; H01L 24/05; H01L 24/06; H01L 24/40; H01L 25/072; H01L 23/3121; H01L 24/32; H01L 24/45; H01L 24/48; H01L 24/49; H01L 24/73; H01L 2224/05553; H01L 2224/0603; H01L 2224/32225; H01L 2224/3701; H01L 2224/37124; H01L 2224/37147; H01L 2224/3716; H01L 2224/40225; H01L 2224/45124; H01L 2224/45144; H01L 2224/45147; H01L 2224/48091; H01L 2224/48106; H01L 2224/48227; H01L 2224/49175; H01L 2224/73221; H01L 2224/73263; H01L 2224/73265; H01L 2924/10253; H01L 2924/10254; H01L 2924/10272; H01L 2924/1033; H01L 2924/13055; H01L 2924/13091

(57) ABSTRACT

A semiconductor module includes: first to third circuit boards respectively connected to first to third terminals; first and second semiconductor elements respectively on the first and second circuit boards; first and second metal wiring boards respectively connecting the first semiconductor element to the second circuit board and the second semiconductor element to the third circuit board. The first metal wiring board includes first and second joining portions and a first coupling portion coupling the first and second joining portions at respective one sides thereof such that the respective one sides of the first and second joining portions face each other. The second metal wiring board includes third and fourth joining portions and a second coupling portion coupling the third and fourth joining portions at respective one sides thereof such that the respective one sides of the third and fourth joining portions face each other.

### CROSS REFERENCE TO RELATED APPLICATIONS

This is a continuation application of International Application PCT/JP2023/008465 filed on Mar. 7, 2023, which claims priority from a Japanese Patent Application No. 2022-051039 filed on Mar. 28, 2022, the contents of which are incorporated herein by reference.

### BACKGROUND

### Technical Field

The present invention relates to a semiconductor module.

### Related Art

A semiconductor module has a substrate, on which a semiconductor element such as an insulated gate bipolar transistor (IGBT), a power metal oxide semiconductor field effect transistor (MOSFET), or a free wheeling diode (FWD) is provided, and is used in an inverter device and the like.

In this type of semiconductor module, for example, as provided in WO 2016/174899, WO 2020/071102, and WO 2016/084622, four semiconductor chips are arranged at a center of a resin case formed in a frame shape. The four semiconductor chips are arranged on an insulating substrate (also referred to as a laminate substrate). A metal wiring board (also referred to as a lead frame) for wiring is disposed on an upper surface electrode of each semiconductor chip. The metal wiring board is formed in a predetermined shape by, for example, stamping a metal plate. One end of each metal wiring board is electrically connected to a circuit pattern on the insulating substrate disposed at the center of the module.

In WO 2016/174899, WO 2020/071102, and WO 2016/084622 described above, a main terminal for external connection is disposed at an outer peripheral edge of a resin case. In this case, depending on the shape of the metal wiring board, a long current path through which a main current flows is likely to be formed, and a problem arises in that inductance of the entire module increases.

The present invention has been made in view of the above description, and an object of the present invention is to provide a semiconductor module capable of reducing inductance by shortening a wiring path.

### SUMMARY

A semiconductor module according to one aspect of the present invention includes: a first circuit board to which one end of a P terminal is electrically connected; a second circuit board to which one end of an M terminal is electrically connected; a third circuit board to which one end of an N terminal is electrically connected; a first semiconductor element disposed on an upper surface of the first circuit board; a second semiconductor element disposed on an upper surface of the second circuit board; a first metal wiring board configured to connect the first semiconductor element and the second circuit board; and a second metal wiring board configured to connect the second semiconductor element and the third circuit board. The first metal wiring board includes a first joining portion having a rectangular shape in a planar view and joined to an upper surface of a main electrode on an upper surface side of the first semiconductor element, a second joining portion having a rectangular shape in a planar view and joined to an upper surface of the second circuit board, and a first coupling portion configured to couple the first joining portion and the second joining portion. The first joining portion and the second joining portion are arranged such that one side of the first joining portion and one side of the second joining portion face each other in a planar view. The first coupling portion couples the one side of the first joining portion and the one side of the second joining portion facing each other. The second metal wiring board includes a third joining portion having a rectangular shape in a planar view and joined to an upper surface of a main electrode on an upper surface side of the second semiconductor element, a fourth joining portion having a rectangular shape in a planar view and joined to an upper surface of the third circuit board, and a second coupling portion configured to couple the third joining portion and the fourth joining portion. The third joining portion and the fourth joining portion are arranged such that one side of the third joining portion and one side of the fourth joining portion face each other in a planar view. The second coupling portion couples the one side of the third joining portion and the one side of the fourth joining portion facing each other.

According to the present invention, it is possible to reduce inductance by shortening a wiring path.

### BRIEF DESCRIPTION OF DRAWINGS

FIG. 1 is a plan view of a semiconductor device according to the present embodiment from above;

FIG. 2 is a plan view in which a sealing resin of FIG. 1 is omitted;

FIG. 3 is a partially enlarged view focusing on one phase of FIG. 2;

FIG. 4 is a cross-sectional view of the semiconductor device along line X-X in FIG. 3;

FIG. 5 is a cross-sectional view of the semiconductor device along line Y-Y in FIG. 3;

FIG. 6 is an equivalent circuit diagram of one phase of the semiconductor device according to the present embodiment;

FIG. 7 is a plan view of a metal wiring board (first metal wiring board) according to the present embodiment;

FIG. 8 is a partially enlarged view focusing on a metal wiring board (first metal wiring board) in FIG. 4;

FIG. 9 is a plan view of another metal wiring board (second metal wiring board) according to the present embodiment;

FIG. 10 is a partially enlarged view focusing on a metal wiring board (second metal wiring board) in FIG. 5;

FIG. 11 is a plan view focusing on a periphery of a metal wiring board in FIG. 3;

FIG. 12 is a plan view of a metal wiring board according to a modification example; and

FIG. 13 is a schematic plan view illustrating an example of a vehicle to which the semiconductor device according to the present invention is applied.

### DETAILED DESCRIPTION

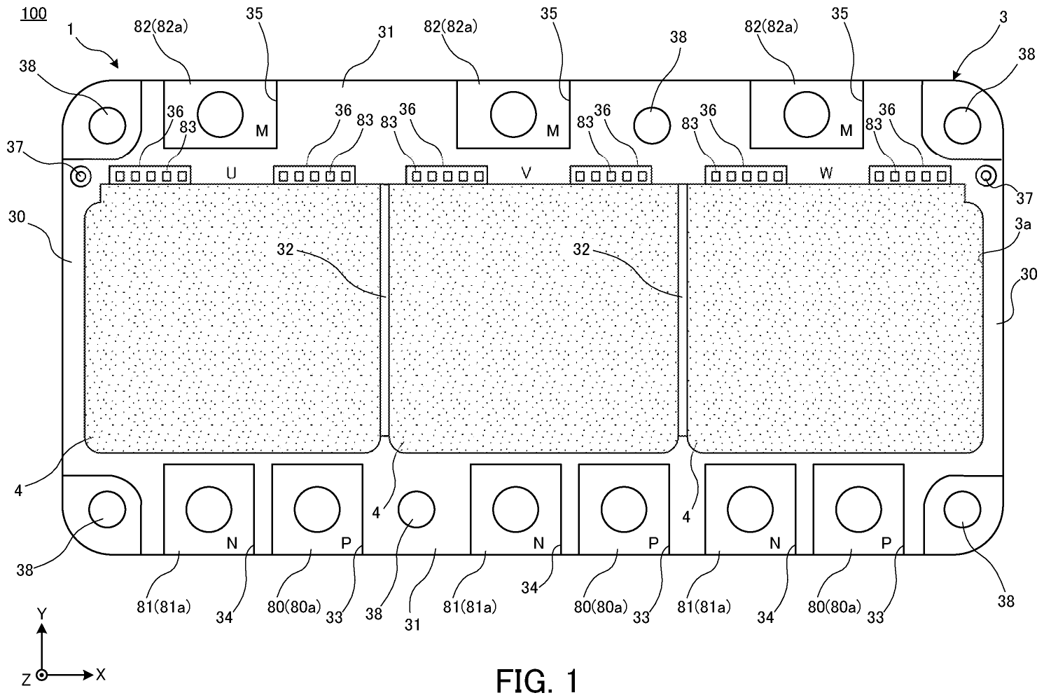

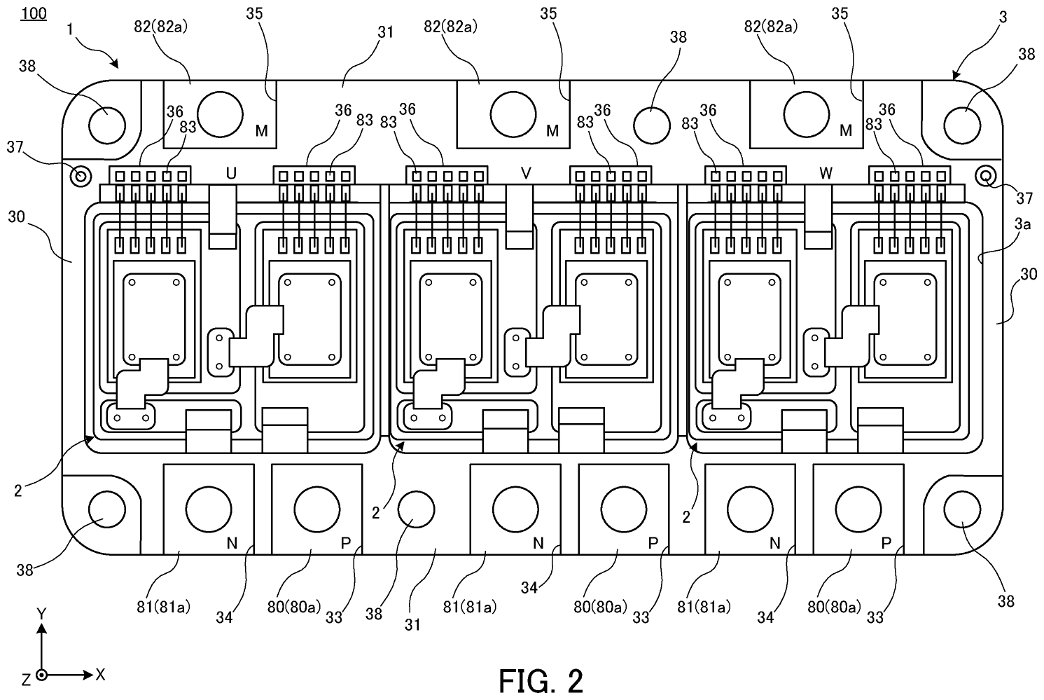

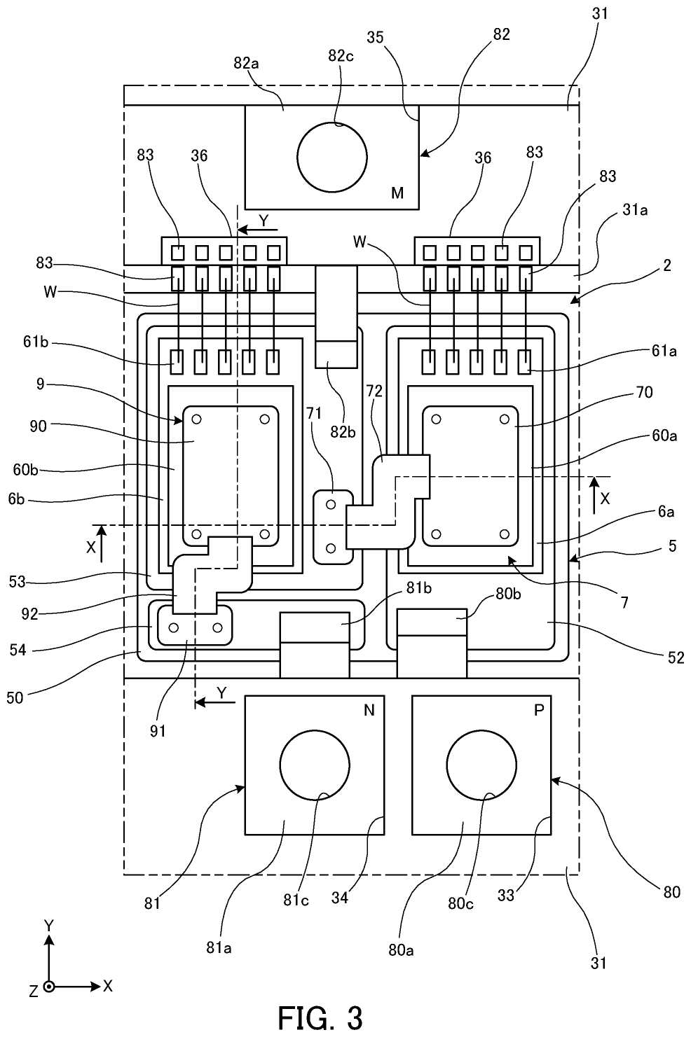

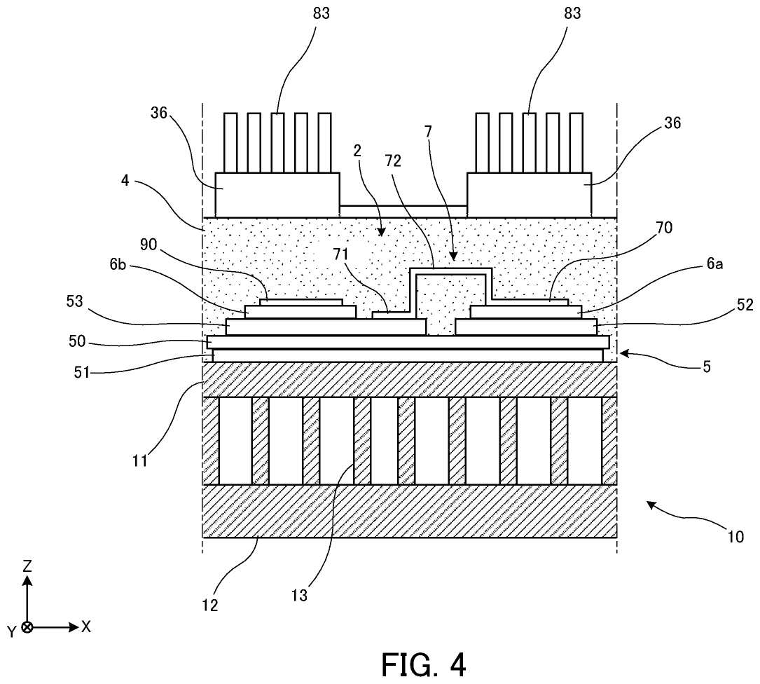

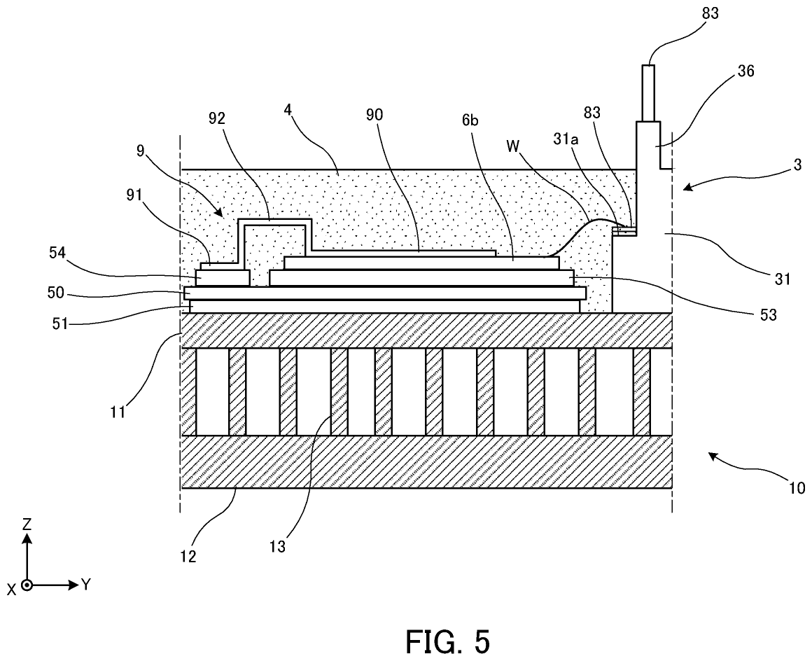

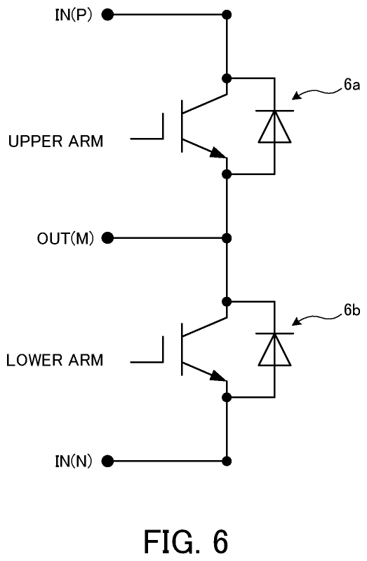

Hereinafter, a semiconductor device to which the present invention can be applied will be described. FIG. 1 is a plan view of a semiconductor device according to the present embodiment from above. FIG. 2 is a plan view in which a sealing resin of FIG. 1 is omitted. FIG. 3 is a partially enlarged view focusing on one phase of FIG. 2. FIG. 4 is a cross-sectional view of the semiconductor device along line X-X in FIG. 3. FIG. 5 is a cross-sectional view of the semiconductor device along line Y-Y in FIG. 3. FIG. 6 is an equivalent circuit diagram of one phase of the semiconductor device according to the present embodiment. In FIGS. 4 and 5, for convenience of illustration, some configurations (for example, a joining material, a boss of a metal wiring board, and the like) are omitted.

In the following drawings, a longitudinal direction of the semiconductor device (cooler) is defined as an X direction, a transverse direction of the semiconductor device is defined as a Y direction, and a height direction (a thickness direction of a substrate) is defined as a Z direction. In addition, the longitudinal direction of the semiconductor device is a direction in which a plurality of wiring boards (or a plurality of phases) are arranged. The illustrated X, Y, and Z axes are orthogonal to each other and form a right-handed system. In some cases, the X direction may be referred to as a right-left direction, the Y direction may be referred to as a front-rear direction, and the Z direction may be referred to as an up-down direction. Further, the +Z direction may be referred to as upward, and the −Z direction may be referred to as downward. In addition, a position on the +Z side may be referred to as a high position, and a position on the −Z side may be referred to as a low position. These directions (front-rear, right-left, and up-down directions) and height are terms used for convenience of description, and the correspondence relationships of each with the XYZ directions may change depending on an attachment posture of the semiconductor device. For example, a heat dissipation surface side (cooler side) of the semiconductor device is referred to as a lower surface side, and the opposite side thereof is referred to as an upper surface side. In the present specification, the term “in a planar view” means a case where an upper surface or a lower surface of the semiconductor device is viewed in the Z direction. In addition, in the present specification, the term “facing” means an arrangement in which two components face each other and may mean not only a relationship of 180° but also a relationship of 170° or larger and 190° including manufacturing variations. The term “parallel” means that two lines may have not only a relationship of 0° but also a relationship of −10° or larger and 10° or smaller including manufacturing variations. In addition, the term “perpendicular” means that two lines may have not only a relationship of 90° but also a relationship of 80° or larger and 100° or smaller including manufacturing variations. The same length, width, and thickness may include those in a range of ±10% including manufacturing variations. In addition, the ratios between widths and thicknesses and the size relationships between the members in the drawings are illustrated in schematic views, and thus are not necessarily the same throughout the drawings. For convenience of description, it is also assumed that the size relationships between the members are exaggerated.

A semiconductor device 100 according to the present embodiment is applied to, for example, a power conversion device such as an inverter of an industrial or in-vehicle motor. As illustrated in FIGS. 1 to 5, the semiconductor device 100 is configured to include a semiconductor module 1 disposed on an upper surface of a cooler 10. Note that the cooler 10 has any configuration with respect to the semiconductor module 1.

The cooler 10 releases heat of the semiconductor module 1 to the outside and has a rectangular shape in a planar view. The cooler 10 may be made of a metal having good heat dissipation properties, such as aluminum, an aluminum alloy, copper, or a copper alloy. The cooler 10 includes a top plate 11, a bottom plate 12, and a plurality of fins 13 arranged between the top plate 11 and the bottom plate 12. The top plate 11, the bottom plate 12, and the plurality of fins 13 are integrated by being joined through brazing or the like.

The semiconductor module 1 includes a plurality of (three in the present embodiment) semiconductor units 2, a case 3 accommodating the plurality of semiconductor units 2, and a sealing resin 4 injected into the case 3.

The semiconductor unit 2 includes a laminate substrate 5 and semiconductor elements 6a and 6b arranged on the laminate substrate 5. In the present embodiment, three semiconductor units 2 are arranged side by side in the X direction. The three semiconductor units 2 form, for example, a U phase, a V phase, and a W phase from a negative side in the X direction and form a three-phase inverter circuit as a whole. Note that the semiconductor unit 2 may be referred to as a power cell.

The laminate substrate 5 is configured to include, for example, a direct copper bonding (DCB) substrate, an active metal brazing (AMB) substrate, or a metal base substrate. The laminate substrate 5 is formed by laminating an insulating plate 50, a heat dissipation plate 51, and a plurality of circuit boards 52 to 54 and is formed in a rectangular shape as a whole in a planar view.

Specifically, the insulating plate 50 includes a plate-shaped body having an upper surface and a lower surface and has a rectangular shape elongated in the X direction in a planar view. The insulating plate 50 may be made of, for example, a ceramic material such as aluminum oxide (Al₂O₃), aluminum nitride (AlN), silicon nitride (Si₃N₄), aluminum oxide (Al₂O₃) or zirconium oxide (ZrO₂).

In addition, the insulating plate 50 may be made of, for example, a thermosetting resin such as an epoxy resin or a polyimide resin, or a composite material obtained by using glass or a ceramic material as a filler in a thermosetting resin. The insulating plate 50 preferably has flexibility and may be made of, for example, a material containing a thermosetting resin. Note that the insulating plate 50 may be referred to as an insulating layer or an insulating film.

The heat dissipation plate 51 has a predetermined thickness in the Z direction and has a rectangular shape elongated in the Y direction in a planar view. For example, the heat dissipation plate 51 is made of a metal plate having good thermal conductivity, such as copper or aluminum. The heat dissipation plate 51 is disposed on a lower surface of the insulating plate 50. A lower surface of the heat dissipation plate 51 is a surface to be attached to the cooler 10 to which the semiconductor module 1 is attached, and the lower surface also functions as a heat dissipation surface (heat dissipation region) for releasing heat of the semiconductor module 1. The heat dissipation plate 51 is joined to the upper surface of the cooler 10 via a joining material (not illustrated) such as solder. The heat dissipation plate 51 may be disposed on the upper surface of the cooler 10 with a thermal conductive material, such as thermal grease or a thermal compound, interposed therebetween.

Each of the plurality of circuit boards 52 to 54 (three in the present embodiment) has a predetermined thickness and has an electrically independent island shape (for example, a rectangular shape in a planar view). The three circuit boards 52 to 54 are arranged at predetermined positions on the upper surface of the insulating plate 50. Note that the shape, the number, the arrangement positions, and the like of the circuit boards 52 to 54 can be appropriately changed without being limited thereto. The circuit boards 52 to 54 may be formed of a metal plate having good thermal conductivity, such as copper or aluminum. The circuit boards 52 to 54 may be referred to as a wiring board, a circuit layer, a circuit pattern, or a wiring pattern.

Specifically, the circuit board 52 (first circuit board) has a rectangular shape elongated in the Y direction in a planar view. The circuit board 52 is disposed closer to a positive side in the X direction on the upper surface of the insulating plate 50.

The circuit board 53 (second circuit board) has a rectangular shape elongated in the Y direction in a planar view. A length of the circuit board 53 in the Y direction is slightly shorter than a length of the circuit board 52 in the Y direction. The circuit board 53 is disposed closer to a negative side in the X direction on the upper surface of the insulating plate 50. That is, the circuit boards 52 and 53 are arranged side by side in the X direction on the upper surface of the insulating plate 50, the circuit board 52 is positioned on the positive side in the X direction, and the circuit board 53 is positioned on the negative side in the X direction. In addition, a side of the circuit board 52 on the negative side in the X direction and a side of the facing circuit board 53 on the positive side in the X direction may be parallel to each other at a predetermined interval.

The circuit board 54 (third circuit board) has a rectangular shape elongated in the X direction in a planar view. A length of the circuit board 54 in the X direction is substantially the same as a length of the circuit board 53 in the X direction. On the upper surface of the insulating plate 50, a space corresponding to a width of the circuit board 53 in the Y direction which is shorter than that of the circuit board 54 is provided at a position on the negative side in the Y direction of the circuit board 53. The circuit board 54 is disposed in the space above the insulating plate 50. That is, the circuit boards 53 and 54 are arranged side by side in the Y direction on the upper surface of the insulating plate 50, the circuit board 53 is positioned on the positive side in the Y direction, and the circuit board 54 is positioned on the negative side in the Y direction. In addition, a length (width) of the circuit board 54 in the Y direction corresponds to a difference between the lengths of the circuit boards 52 and 53 in the Y direction. In addition, a side of the circuit board 53 on the negative side in the Y direction and a side of the facing circuit board 54 on the positive side in the Y direction may be parallel to each other at a predetermined interval.

These circuit boards 52 to 54 constitute a part of a wiring path (main current wiring path) of a main current flowing in the module.

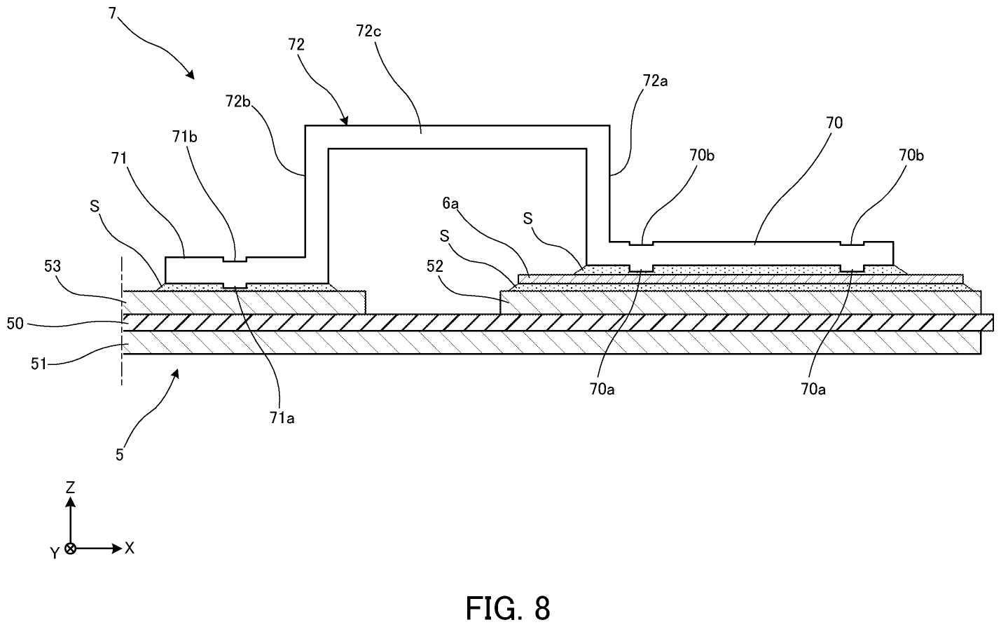

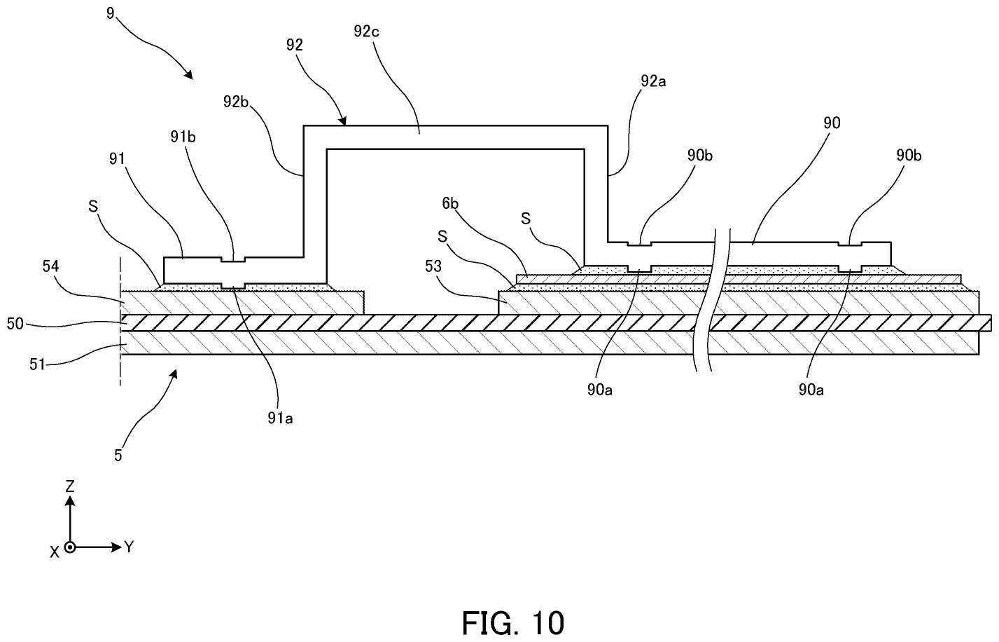

The semiconductor element 6a is disposed on an upper surface (upper board surface) of the circuit board 52 with a joining material S (see FIG. 8) such as solder interposed therebetween. In addition, a side of the circuit board 52 on the negative side in the X direction and a side of the semiconductor element 6 on the negative side in the X direction may be arranged to be parallel to each other at a predetermined interval. The semiconductor element 6 is disposed on an upper surface (upper board surface) of the circuit board 53 with the joining material S (see FIG. 10) such as solder interposed therebetween. In addition, a side of the circuit board 53 on the positive side in the X direction and a side of the semiconductor element 6 on the positive side in the X direction may be arranged to be parallel to each other at a predetermined interval. Further, the side of the circuit board 53 on the negative side in the Y direction and the side of the semiconductor element 6b on the negative side in the Y direction may be arranged to be parallel to each other at a predetermined interval. The joining material S may be a conductive material and may be, for example, solder or a metal sintered material. The semiconductor elements 6a and 6b are each formed by a semiconductor substrate made of silicon (Si) or the like to have a rectangular shape in a planar view.

In addition, the semiconductor elements 6a and 6b may each be configured to include a wide bandgap semiconductor element (also referred to as a wide gap semiconductor element) formed by a wide bandgap semiconductor substrate made of silicon carbide (SiC), gallium nitride (GaN), diamond, or the like, in addition to the above-described silicon.

For the semiconductor elements 6a and 6b, a switching element such as an insulated gate bipolar transistor (IGBT) and a power metal oxide semiconductor field effect transistor (MOSFET) is used. Further, a diode such as a free wheeling diode (FWD) may be used.

In the present embodiment, the semiconductor elements 6a and 6b are each configured of a reverse conducting (RC)-IGBT element into which functions of an insulated gate bipolar transistor (IGBT) element and a free wheeling diode (FWD) element are integrated (for example, see FIG. 6).

Note that the semiconductor elements 6a and 6b are not limited thereto and may be formed by combining the above-described switching element, diodes, and the like. For example, the IGBT element and the FWD element may be configured separately. In addition, as the semiconductor element 6, a reverse blocking (RB)-IGBT or the like having a sufficient withstand voltage against a reverse bias may be used.

In addition, the shapes, the number, the arrangement positions, and the like of the semiconductor elements 6a and 6b can be appropriately changed. For example, in the present embodiment, two semiconductor elements (one semiconductor element 6a and one semiconductor element 6b) are arranged per phase. The two semiconductor elements 6a and 6b are connected in series. In addition, as illustrated in FIG. 6, of the two semiconductor elements 6, the semiconductor element 6a (first semiconductor element) disposed on the upper surface of the circuit board 52 (first circuit board) may constitute an upper arm, and the semiconductor element 6b (second semiconductor element) disposed on the upper surface of the other circuit board 53 (second circuit board) may constitute a lower arm. That is, the circuit board 52 constitutes a part of the main current path of the upper arm, and the circuit board 53 constitutes a part of the main current path of the lower arm. As described above, each of the semiconductor element 6a and the semiconductor element 6b may be disposed for each phase. Each semiconductor element is disposed for each phase, and the wiring path is further shortened such that inductance can be reduced. In addition, a plurality of semiconductor elements 6a and semiconductor elements 6b may be arranged, and the number of semiconductor elements 6a may be the same as the number of semiconductor elements 6b. By connecting the plurality of semiconductor elements 6a in parallel and connecting the plurality of semiconductor elements 6b in parallel, the module can have a large capacity. In addition, when the number of semiconductor elements 6a is the same as the number of semiconductor elements 6b, it is possible to suppress a current imbalance between the upper arm and the lower arm.

The semiconductor element 6a (6b) configured as described above has a rectangular shape in a planar view and has an upper surface (upper element surface) and a lower surface (lower element surface) in an XY plane, and an electrode is formed on each of the surfaces. For example, a main electrode 60a (60b) and a control electrode 61a (61b) are formed on the upper surface of the semiconductor element 6a (6b), and a main electrode (not illustrated) is formed on the lower surface of the semiconductor element 6a (6b). The main electrode 60a (60b) on the upper surface and the main electrode on the lower surface are electrodes through which a main current flows, and each has a rectangular shape in a planar view having an area occupying a large part of the upper surface (upper element surface) of the semiconductor element 6a (6b). On the other hand, the control electrode 61a (61b) has a much smaller rectangular shape in a planar view than the main electrode 60a (60b). For example, in the present embodiment, five control electrodes 61a (61b) are formed for one semiconductor element 6a (6b). On the upper surface of the semiconductor element 6a (6b), the main electrode 60a (60b) is formed on one side (a side on a −Y side), and the control electrodes 61a (61b) are arranged closer to a side portion on the other side (a side on a +Y side) which is an opposite side. Note that the arrangement of the individual electrodes is not limited thereto and can be appropriately changed.

Also, in a case where the semiconductor elements 6a and 6b are IGBT elements, the main electrode on the upper surface side may be referred to as an emitter electrode, and the main electrode on the lower surface side may be referred to as a collector electrode. In addition, in a case where the semiconductor elements 6a and 6b are MOSFET elements, the main electrode on the upper surface side may be referred to as a source electrode, and the main electrode on the lower surface side may be referred to as a drain electrode.

In addition, the control electrodes 61a and 61b may include a gate electrode. The gate electrode is an electrode for controlling a gate for turning on and off the main current. In addition, the control electrodes 61a and 61b may include an auxiliary electrode. For example, the auxiliary electrode may be an auxiliary source electrode or an auxiliary emitter electrode electrically connected to the main electrode on the upper surface side and serving as a reference potential with respect to a gate potential. In addition, the auxiliary electrode may be a temperature sensing electrode which measures a temperature of the semiconductor element. Such electrodes (the main electrode 60a and the control electrode 61a) formed on the upper surface of the semiconductor element 6a and electrodes (the main electrode 60b and the control electrode 61b) formed on the upper surface of the semiconductor element 6b may be generally referred to as upper surface electrodes, and the electrodes (main electrodes) formed on the lower surfaces of the semiconductor elements 6a and 6b may be referred to as lower surface electrodes.

In addition, each of the semiconductor elements 6a and 6b in the present embodiment may be a so-called vertical switching element in which functional elements such as transistors are formed on the semiconductor substrate in a thickness direction or a horizontal switching element in which these functional elements are formed in a plane direction.

The main electrode on the lower surface side of the semiconductor element 6a is joined to the upper surface of the circuit board 52 (first circuit board) via a joining material S (see FIG. 8). In addition, the main electrode on the lower surface side of the semiconductor element 6b is joined to the upper surface of the circuit board 53 (second circuit board) via a joining material S (see FIG. 10). The main electrode 60 on the upper surface side of the semiconductor element 6a and the upper surface of the circuit board 53 (second circuit board) are electrically connected by a metal wiring board 7 (first metal wiring board). In addition, the main electrode 60 on the upper surface side of semiconductor element 6b (second semiconductor element) and the upper surface of the circuit board 54 (third circuit board) are electrically connected by metal wiring boards 7 and 9. The metal wiring boards 7 and 9 constitute a main current wiring member and function as a part of a path (main current path) of a main current flowing in the semiconductor module 1.

The metal wiring boards 7 and 9 are each configured of a plate-shaped body having an upper surface and a lower surface. A thickness of the metal wiring board 7 may be 0.1 mm or more and 2.5 mm or less. The metal wiring boards 7 and 9 are each formed of, for example, a metal such as copper, a copper alloy, an aluminum alloy, or an iron alloy. The metal wiring board 7 is formed into a predetermined shape by, for example, stamping. In addition, surfaces of the metal wiring boards 7 and 9 may be plated to prevent oxidation and corrosion. By plating, adhesion to a resin (a coating layer interposed between the metal wiring board and the sealing resin 4) can be improved. Note that a shape of each of the metal wiring boards 7 and 9 to be described below is merely an example and can be appropriately changed. In addition, the metal wiring boards 7 and 9 may be referred to as a lead frame. Hereinafter, the metal wiring boards 7 and 9 will be described separately, but the corresponding configurations are assumed to be common.

The metal wiring board 7 according to the present embodiment has a crank shape in a planar view, and the crank shape is formed by being bent a plurality of times in different directions in a side view. Specifically, the metal wiring board 7 includes a first joining portion 70, a second joining portion 71, and a coupling portion 72. The first joining portion 70 is joined to the upper surface (main electrode 60) of the semiconductor element 6a via the joining material S (for example, see FIG. 8). The second joining portion 71 is joined to the upper surface of another wiring board (circuit board 53) via the joining material S. The joining material S may be a conductive material and may be, for example, solder or a metal sintered material. The coupling portion 72 (first coupling portion) couples the first joining portion 70 and the second joining portion 71.

One end of the metal wiring board 7 is connected to the semiconductor element 6a on the upper arm side, and the other end of the metal wiring board 7 is connected to the upper surface of the circuit board 53.

The metal wiring board 9 according to the present embodiment has a crank shape in a planar view, and the crank shape is formed by being bent a plurality of times in different directions in a side view. Specifically, the metal wiring board 9 includes a third joining portion 90, a fourth joining portion 91, and a coupling portion 92. The third joining portion 90 is joined to the upper surface (main electrode 60) of the semiconductor element 6b via the joining material S (for example, see FIG. 10). The fourth joining portion 91 is joined to the upper surface of another wiring board (circuit board 54) via the joining material S. The joining material S may be a conductive material and may be, for example, solder or a metal sintered material. The coupling portion 92 (second coupling portion) couples the third joining portion 90 and the fourth joining portion 91.

In addition, one end of the metal wiring board 9 is connected to the semiconductor element 6b on the lower arm side, and the other end of the metal wiring board 9 is connected to the upper surface of the circuit board 54. Detailed structures of the metal wiring boards 7 and 9 will be described below.

Note that the shape, the number, arrangement positions, and the like of the metal wiring boards 7 and 9 described above are merely examples and can be appropriately changed without being limited thereto. A detailed description will be provided below, but in the present embodiment, the semiconductor elements 6a and 6b and the metal wiring boards 7 and 9 described above and a main terminal and the like to be described below may form, for example, an inverter circuit illustrated in FIG. 6.

A periphery of the laminate substrate 5, the semiconductor elements 6a and 6b, and the metal wiring boards 7 and 9 is surrounded by the case 3. The case 3 has a quadrangular annular tubular or frame shape in a planar view. The case 3 is made of, for example, a thermoplastic resin. Examples of the thermoplastic resin include a polyphenylene sulfide (PPS) resin, a polybutylene terephthalate (PBT) resin, a polybutylene succinate (PBS) resin, a polyamide (PA) resin, a polyether ether ketone (PEEK) resin, and an acrylonitrile butadiene styrene (ABS) resin. An inorganic filler for improving strength and/or functionality may be mixed into the resin. The case 3 is molded by injection molding using the thermoplastic resin.

The case 3 has a rectangular frame shape and has an opening portion 3a at the center thereof. Specifically, the case 3 includes a pair of side walls 30 facing each other in the X direction and a pair of side walls 31 facing each other in the Y direction and is formed into the rectangular frame shape by connecting end portions of the side walls. The pair of side walls 31 is longer than the pair of side walls 30.

In addition, the pair of side walls 31 is coupled by two partition walls 32 extending in the Y direction. Consequently, an inner space of the case 3 is partitioned into three spaces arranged in the X direction. The semiconductor unit 2 and the metal wiring boards 7 and 9 are accommodated in the respective spaces. That is, the three semiconductor units 2 and metal wiring boards 7 and 9 are accommodated in the space defined by the frame-shaped case 3. A lower end of the case 3 adheres to an upper surface of the cooler 10 (top plate 11) via an adhesive. The adhesive is preferably, for example, an epoxy-based or silicone-based adhesive.

The case 3 is provided with main terminals (a P terminal (first terminal) 80, an N terminal (third terminal) 81, and an M terminal (second terminal) 82) for external connection and a control terminal 83 for control. Regarding the pair of side walls 31 facing each other in a transverse direction (Y direction) of the case 3, the side wall 31 positioned on the negative side in the Y direction has recesses 33 and 34 having a quadrangular shape in a planar view.

One P terminal 80 (a terminal portion 80a to be described below) is disposed in the recess 33. The P terminal 80 is disposed for each phase. An end portion of the P terminal 80 (a tip of a plate-shaped portion 80b to be described below) is connected to the circuit board 52.

The P terminal 80 is formed by integrally molding or coupling the terminal portion 80a and the plate-shaped portion 80b together. The terminal portion 80a is formed of a square nut having a predetermined thickness. The terminal portion 80a has a screw hole 80c penetrating the center of the terminal portion in a thickness direction. The terminal portion 80a is provided on one end (base end) side of the plate-shaped portion 80b.

The plate-shaped portion 80b has a flat plate shape having an upper surface and a lower surface. The plate-shaped portion 80b has an elongated shape elongated in the Y direction in a planar view. In addition, the other end (tip) of the plate-shaped portion 80b is electrically connected to the upper surface of the circuit board 52.

Similarly, the N terminal 81 (a terminal portion 81a to be described below) is disposed in the recess 34. One N terminal 81 is disposed for each phase. An end portion of the N terminal 81 (a tip of the plate-shaped portion 81b) is connected to the circuit board 54.

The N terminal 81 is formed by integrally molding or coupling the terminal portion 81a and the plate-shaped portion 81b together. The terminal portion 81a is formed of a square nut having a predetermined thickness. The terminal portion 81a has a screw hole 81c penetrating the center of the terminal portion in the thickness direction. The terminal portion 81a is provided on one end (base end) side of the plate-shaped portion 81b.

The plate-shaped portion 81b has a flat plate shape having an upper surface and a lower surface. The plate-shaped portion 81b has an elongated shape elongated in the Y direction in a planar view. In addition, the other end (tip) of the plate-shaped portion 81b is joined to the upper surface of the circuit board 54 via a joining material (not illustrated).

In addition, regarding the pair of side walls 31 facing each other in the transverse direction (Y direction) of the case 3, the side wall 31 on the positive side in the Y direction has a recess 35 having a quadrangular shape in a planar view. The M terminal 82 (a terminal portion 82a to be described below) is disposed in the recess 35. One M terminal 82 is disposed for each phase. An end portion of the M terminal 82 (a tip of the plate-shaped portion 82b) is connected to the circuit board 53.

The M terminal 82 is formed by integrally molding or coupling the terminal portion 82a and the plate-shaped portion 82b together. The terminal portion 82a is formed of a square nut having a predetermined thickness. The terminal portion 82a has a screw hole 82c penetrating the center of the terminal portion in the thickness direction. The terminal portion 82a is provided on one end (base end) side of the plate-shaped portion 82b.

The plate-shaped portion 82b has a flat plate shape having an upper surface and a lower surface. The plate-shaped portion 82b has an elongated shape elongated in the Y direction in a planar view. In addition, the other end (tip) of the plate-shaped portion 82b is joined to the upper surface of the circuit board 53 via a joining material (not illustrated).

The P terminal 80, the N terminal 81, and the M terminal 82 correspond to P, N, and M in FIG. 6. As illustrated in FIG. 6, the P terminal 80 is electrically connected to the collector electrode (the main electrode on the lower surface side) of the semiconductor element 6a (first semiconductor element) constituting the upper arm. The M terminal 82 is electrically connected to the emitter electrode (the main electrode on the upper surface side) of the semiconductor element 6a and the collector electrode (the main electrode on the lower surface side) of the semiconductor element 6b (second semiconductor element) constituting the lower arm. The N terminal 81 is electrically connected to the emitter electrode (the main electrode on the upper surface side) of the semiconductor element 6b. The P terminal 80 may be referred to as a positive terminal (input terminal). The N terminal 81 may be referred to as a negative terminal (input terminal). The M terminal 82 may be referred to as an intermediate terminal (output terminal). Each of these terminals constitutes a metal wiring board through which the main current flows. One end of each of the P terminal 80, the N terminal 81, and the M terminal 82 constitutes a main terminal connectable to an external conductor. As described above, one end of each of the P terminal 80, the N terminal 81, and the M terminal 82 is electrically connected to a predetermined wiring board.

In addition, end portions of the main terminals (the P terminal 80, the N terminal 81, and the M terminal 82) and predetermined circuit boards may be joined by laser joining or ultrasonic joining. In addition, the end portions of the main terminals and the predetermined circuit boards may each be joined via a joining material. In addition, a metal block having a predetermined thickness may be interposed between the end of each of the main terminals and each predetermined circuit board. Further, the end of each of the main terminals and each predetermined circuit board may be electrically connected by a bonding wire. That is, the end of each of the main terminals and each predetermined circuit board may be electrically connected, or another configuration may be interposed between the end of each of the main terminal and each predetermined circuit board.

For example, each of these main terminals is made of a metal material, such as a copper material, a copper-alloy-based material, an aluminum-alloy-based material, or an iron-alloy-based material. In addition, a plating film may be formed on a surface of each of these main terminals. The plating film may be made of, for example, nickel, a nickel alloy, tin, a tin alloy, or the like. Note that shapes, arrangement positions, the number, and the like of these terminals can be appropriately changed without being limited thereto.

A pair of column portions 36 protruding vertically in the Z direction is formed on the upper surface of a side wall on the positive side in the Y direction. The column portion 36 has an elongated shape elongated in the X direction in a planar view along the opening portion 3a. The two column portions 36 are arranged per phase and are arranged in the X direction. In addition, a step portion 31a which is one step lower than the upper surface of the side wall 31 along the opening portion 3a is formed on an inner side (the negative side in the Y direction) of the column portion 36.

A plurality of control terminals 83 are embedded in the column portion 36. Five control terminals 83 are embedded in one column portion 36. One end of the control terminal 83 protrudes from an upper surface of the column portion 36 and extends upward in the Z direction. The other end of the control terminal 83 is exposed on an upper surface of the step portion 31a. Five control terminals 83 are arranged for one semiconductor element 6, and ten control terminals are arranged for one phase. These control terminals 83 are provided to correspond to the control electrodes 61. Note that the number of the arranged control terminals 83 can be appropriately changed without being limited thereto.

For example, the control terminal 83 is made of a metal material such as a copper material, a copper-alloy-based material, an aluminum-alloy-based material, or an iron-alloy-based material. The control terminal 83 is integrally molded (insert-molded) to be embedded in the case 3. In addition, a plating film may be formed on a surface of the control terminal 83. The plating film may be made of, for example, nickel, a nickel alloy, tin, a tin alloy, or the like. Note that shapes, arrangement positions, and the like of the control terminals 83 can be appropriately changed without being limited thereto.

In addition, a positioning pin 37 extending in the Z direction is provided on an upper surface of the side wall 30. The positioning pin 37 is provided adjacent to a negative side in the X direction of the column portion 36 on the upper surface of the side wall 30 on the negative side in the X direction. In addition, the positioning pin 37 is also provided adjacent to a positive side in the X direction of the column portion 36 on the upper surface of the side wall 30 on the positive side in the X direction.

In addition, the case 3 has a plurality of through-holes 38 along an outer peripheral edge thereof. The through-holes 38 penetrate the case to the cooler 10.

The corresponding control electrode 61a (61b) and the control terminal 83 are electrically connected by a wiring member W. As the wiring member W, a conductive wire (bonding wire) is used. As a material of the conductive wire, any one of gold, copper, aluminum, a gold alloy, a copper alloy, and an aluminum alloy or any combination thereof can be used. As the wiring member, a member other than the conductive wire can be used. For example, a ribbon can be used as the wiring member.

An internal space defined by the case 3 is filled with the sealing resin 4. The case 3 may be filled with the sealing resin 4 until the upper surface of the sealing resin reaches the upper end of the case 3. Consequently, various components (the three semiconductor units 2, the metal wiring board 7, the terminals, the wiring member W, and the like) disposed in the case 3 are sealed.

The sealing resin 4 may be made of, for example, a thermosetting resin. The sealing resin 4 preferably contains at least one of an epoxy resin, a silicone resin, a phenol resin, and a melamine resin. As the sealing resin 4, for example, an epoxy resin mixed with an inorganic filler is suitable from the viewpoint of insulation, heat resistance, and heat dissipation.

Meanwhile, in the semiconductor device 100, there is a demand for inductance reduction of the entire module from the viewpoint of switching responsiveness. In addition, it is assumed that main wiring functioning as a part of the main current path of the module is formed by the metal wiring board 7 such as a lead frame.

In this case, the shape of the metal wiring board 7 or 9 can affect a length of the main current path of the entire module. Moreover, the shape of the metal wiring board 7 or 9 can affect an arrangement posture of the metal wiring board 7 or 9 at the time of module assembly. More specifically, since a current tends to flow through the shortest path in the metal wiring board 7, the shape or arrangement of the metal wiring board 7 or 9 can affect the length of the main current path of the entire module.

More specifically, when the metal wiring boards 7 and 9 are joined, the metal wiring boards 7 and 9 are arranged on the laminate substrate 5 or the semiconductor elements 6a and 6b in advance. At that time, when the position of the center of gravity is shifted due to the shape of each of the metal wiring boards 7 and 9, the metal wiring boards 7 and 9 may be joined to, in an inclined state, the laminate substrate 5 or the semiconductor elements 6a and 6b. That is, it can be assumed that the self-standing stability of the metal wiring boards 7 and 9 as a single body significantly affects the postures thereof at the time of joining. The postures of the metal wiring boards 7 and 9 at the time of joining not only can affect the mechanical strength of a joining part but also can affect output characteristics at the time of operation.

As described above, the shapes of the metal wiring boards 7 and 9 are considered one important factor that affects not only the electrical characteristics but also the mechanical strength of the entire module.

Therefore, the present inventors have arrived at the present invention by focusing on the shapes of the metal wiring boards 7 and 9 and a layout of the main current path (main terminals and wiring pattern) of the entire module. Hereinafter, a specific configuration thereof will be described in detail.

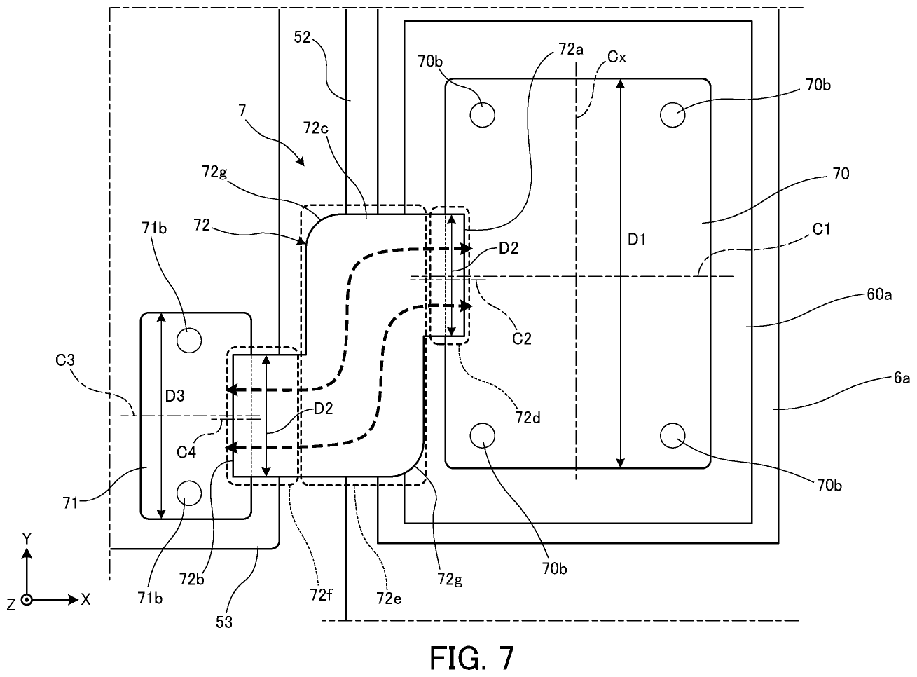

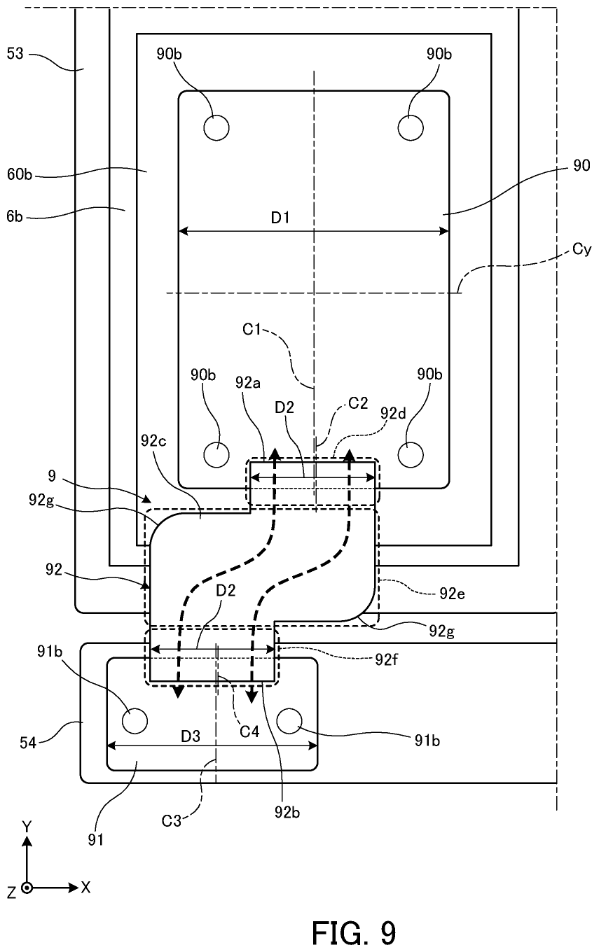

First, a detailed structure of the metal wiring board according to the present embodiment will be described with reference to FIGS. 3 and 7 to 10. FIG. 7 is a plan view of the metal wiring board (first metal wiring board) according to the present embodiment. FIG. 8 is a partially enlarged view focusing on the metal wiring board (first metal wiring board) in FIG. 4. FIG. 9 is a plan view of another metal wiring board (second metal wiring board) according to the present embodiment. FIG. 10 is a partially enlarged view focusing on the metal wiring board (second metal wiring board) in FIG. 5. In FIGS. 7 and 8, the metal wiring board 7 (first metal wiring board) positioned on the upper arm side (right side in FIG. 3) will be described as an example. In FIGS. 9 and 10, the metal wiring board 9 (second metal wiring board) positioned on the lower arm side (left side in FIG. 3) will be described as an example.

As illustrated in FIGS. 3, 7, and 8, the metal wiring board 7 includes the first joining portion 70, the second joining portion 71, and the coupling portion 72. The coupling portion 72 further has a first rising portion 72a, a second rising portion 72b, and a horizontal portion 72c.

The first joining portion 70 is formed in a rectangular shape smaller than the main electrode 60a of the semiconductor element 6a in a planar view. For example, the first joining portion 70 has a rectangular shape with long sides in the Y direction and short sides in the X direction. The first joining portion 70 includes a plate-shaped part having an upper surface and a lower surface in an XY plane and having a thickness in the Z direction. The first joining portion 70 is joined to a widthwise center of one side of the main electrode 60a in the X direction on the upper surface side. That is, the side of the first joining portion 70 in the X direction is formed to include the center line of the main electrode 60a in the X direction on the upper surface side. More preferably, a center line Cx of the first joining portion 70 in the X direction is set within a range of 10% or smaller of a length of the main electrode 60a in the X direction from the center line of the main electrode 60a in the X direction on the upper surface side. Still more preferably, the center line of the main electrode 60a in the X direction on the upper surface side coincides with the center line Cx of the first joining portion 70 in the X direction. In addition, the first joining portion 70 is joined to a widthwise center of one side of the main electrode 60a in the Y direction on the upper surface side. That is, the side of the first joining portion 70 in the Y direction is formed to include a center line of the main electrode 60a in the Y direction on the upper surface side. More preferably, a center line C1 of the first joining portion 70 in the Y direction is set within a range of 10% or smaller of a length of the main electrode 60a in the Y direction from the center line of the main electrode 60a in the Y direction on the upper surface side. Still more preferably, the center line of the main electrode 60a in the Y direction on the upper surface side coincides with the center line C1 of the first joining portion 70 in the Y direction.

In addition, a plurality of (four in the present embodiment) bosses 70a protruding downward are formed on the lower surface of the first joining portion 70. The bosses 70a are arranged at respective positions corresponding to four corners of the first joining portion 70. In addition, recesses 70b are formed at positions corresponding to the positions immediately above the bosses 70a, in the upper surface of the first joining portion 70. The first joining portion 70 is disposed to face the upper surface electrode (main electrode 60a) of the semiconductor element 6 in the Z direction and is joined thereto via the joining material S.

In addition, the upper surface of the first joining portion 70 may have a roughened surface having a surface roughness larger than that of other parts. The roughened surface can be formed by intentionally exposing the surface to, for example, a solvent, a laser, a die, or the like. According to this roughened surface, adhesion to a resin is improved as an anchor effect.

For example, as illustrated in FIG. 7, the second joining portion 71 is formed in a rectangular shape with short sides in the X direction and long sides in the Y direction in a planar view. The second joining portion 71 includes a plate-shaped part having an upper surface and a lower surface in an XY plane and having a thickness in the Z direction.

In addition, a plurality of (two in the present embodiment) bosses 71a protruding downward are formed on the lower surface of the second joining portion 71. The two bosses 71a are arranged side by side in a longitudinal direction of the second joining portion 71. In addition, recesses 71b formed at positions corresponding to positions immediately above the bosses 71a are formed in the upper surface of the second joining portion 71. The second joining portion 71 is disposed to face the upper surface of the circuit board 53 in the Z direction and is joined thereto via the joining material S.

The first joining portion 70 and the second joining portion 71 are arranged to partially face each other in the X direction in a planar view. That is, one side of the first joining portion 70 and one side of the second joining portion 71 are arranged in parallel at a predetermined distance. Further, the one side of the first joining portion 70 and the one side of the second joining portion 71 are arranged to obliquely face each other in a planar view. For example, as illustrated in FIG. 7, a long side of the first joining portion 70 and a long side of the second joining portion 71 are arranged in parallel at a predetermined distance and partially face each other.

The coupling portion 72 (first coupling portion) couples the first joining portion 70 and the second joining portion 71 described above together. The coupling portion 72 includes a plate-shaped part formed in a gate shape or an arch shape in a side view. Specifically, the coupling portion 72 includes a first rising portion 72a rising upward from the one side of the first joining portion 70, a second rising portion 72b rising upward from the one side of the second joining portion 71, and a horizontal portion 72c coupling an upper end of the first rising portion 72a and an upper end of the second rising portion 72b together. The first rising portion 72a constitutes one end part of the coupling portion 72, and the second rising portion 72b constitutes the other end part of the coupling portion 72.

The first rising portion 72a rises perpendicularly with respect to the first joining portion 70 from the one side (for example, the one side facing the second joining portion 71) of the first joining portion 70. The first rising portion 72a includes a plate-shaped part having a main surface on a YZ plane parallel to the one side of the first joining portion 70, a side surface on a ZX plane, a width in the Y direction, and a thickness in the X direction (see FIGS. 7 and 8). The width of the first rising portion 72a is smaller than a width of the connected first joining portion 70 (a length of the one side of the first joining portion 70). The thickness of the first rising portion 72a may be substantially the same as a thickness of the first joining portion 70. For example, the thickness of the first rising portion 72a may be 80% or larger and 120% or smaller of the thickness of the first joining portion 70.

In addition, the first rising portion 72a is coupled to the widthwise center of the one side of the first joining portion 70. That is, the first rising portion 72a is formed to include the widthwise center of the one side of the first joining portion 70. More preferably, a widthwise center line

C2 of the first rising portion 72a is set within a range of 10% or smaller of the width of the one side of the first joining portion 70 from the widthwise center line C1 of the one side of the first joining portion 70. More preferably, as illustrated in FIG. 7, the widthwise center line C2 of the first rising portion 72a coincides with the widthwise center line C1 of the one side of the first joining portion 70. In FIG. 7, the center lines C1 and C2 are slightly shifted from each other in the Y direction for convenience of illustration. That is, in the present embodiment, it is not excluded that the center lines C1 and C2 completely coincide with each other.

The second rising portion 72b rises perpendicularly with respect to the second joining portion 71 from the one side (for example, the one side facing the first joining portion 70) of the second joining portion 71. The second rising portion 72b includes a plate-shaped part having a main surface on a YZ plane parallel to the one side of the second joining portion 71, a side surface on a ZX plane, a width in the Y direction, and a thickness in the X direction (see

FIGS. 7 and 8). The width of the second rising portion 72b is smaller than a width of the connected second joining portion 71 (a length of the one side of the second joining portion 71). The thickness of the second rising portion 72b may be substantially the same as a thickness of the second joining portion 71. For example, the thickness of the second rising portion 72b may be 80% or larger and 120% or smaller of the thickness of the second joining portion 71.

In addition, the second rising portion 72b is coupled to the widthwise center of the one side of the second joining portion 71. That is, the second rising portion 72b is formed to include the widthwise center of the one side of the second joining portion 71. More preferably, a widthwise center line C4 of the second rising portion 72b is set within a range of 10% or smaller of the width of the one side of the second joining portion 71 from a widthwise center line C3 of the one side of the second joining portion 71. More preferably, as illustrated in FIG. 7, the widthwise center line C4 of the second rising portion 72b coincides with the widthwise center line C3 of the one side of the second joining portion 71. In FIG. 7, the center lines C3 and C4 are slightly shifted from each other in the Y direction for convenience of illustration. That is, in the present embodiment, it is not excluded that the center lines C3 and C4 completely coincide with each other.

The first rising portion 72a and the second rising portion 72b are arranged to partially face each other thereof in the X direction in a planar view. That is, one surface of the first rising portion 72a and one surface of the second rising portion 72b are arranged in parallel at a predetermined distance. Further, the one surface of the first rising portion 72a and the one surface of the second rising portion 72b are arranged to obliquely face each other in a planar view. For example, as illustrated in FIG. 7, the one surface of the first rising portion 72a and the one surface of the second rising portion 72b are arranged in parallel at the predetermined distance and partially face each other. In addition, the thickness of the first rising portion 72a and the thickness of the second rising portion 72b are preferably the same.

In addition, a height of the upper end of the first rising portion 72a and a height of the upper end of the second rising portion 72b are preferably the same. On the other hand, a lower end of the first rising portion 72a is positioned to be preferably higher than a lower end of the second rising portion 72b. That is, the first joining portion 70 is provided at a position (position on the positive side in the Z direction) higher than the second joining portion 71. More specifically, the first joining portion 70 is preferably provided at a position higher than the second joining portion 71 by the thickness of the semiconductor element 6a.

The horizontal portion 72c includes a plate-shaped part having an upper surface and a lower surface in an XY plane and having a thickness in the Z direction. In addition, the horizontal portion 72c has a crank shape bent twice at a substantially right angle in a planar view. A width of the horizontal portion 72c is preferably the same as that of the first rising portion 72a or the second rising portion 72b.

More specifically, as illustrated in FIG. 7, the horizontal portion 72c includes a first extending portion 72d, a second extending portion 72e, and a third extending portion 72f. The first extending portion 72d has a rectangular shape extending in the X direction with a predetermined width from the one side of the first joining portion 70 facing the second joining portion 71. The first extending portion 72d is long in the Y direction. The second extending portion 72e is continuous to one side of the first extending portion 72d and has a rectangular shape extending in the Y direction with a predetermined width. The second extending portion 72e is long in the Y direction. The third extending portion 72f has a rectangular shape extending in the X direction with a predetermined width from the one side of the second joining portion 71 facing the first joining portion 70. The third extending portion 72f is long in the Y direction. The third extending portion 72f is continuous to one side of the second extending portion 72e. In addition, in the horizontal portion 72c (second extending portion 72e), the first extending portions 72d (fillets) are formed at edge parts (two diagonally facing corner portions), respectively, in a planar view.

The thickness of the metal wiring board 7 configured as described above is a uniform thickness from the first joining portion 70 to the second joining portion 71, but is not limited thereto. For example, the thickness of the metal wiring board 7 is not necessarily uniform from the first joining portion 70 to the second joining portion 71 and may be partially thin.

In the present embodiment, one end of the coupling portion 72 is coupled to the widthwise center of the one side of the first joining portion 70, and the other end of the coupling portion 72 is coupled to the widthwise center of the one side of the second joining portion 71. Consequently, the position of the center of gravity of the metal wiring board 7 alone is positioned near the center of the coupling portion 72 (horizontal portion 72c). Hence, the self-standing stability of the metal wiring board 7 alone can be improved, and it is possible to prevent inclination and the like of the joining portion by suppressing a posture change at the time of joining as much as possible.

The coupling is also performed on a widthwise center of the upper surface electrode (main electrode 60a) of the semiconductor element 6a. Therefore, a current bias in the width direction (Y direction) in the upper surface electrode (main electrode 60a) can be suppressed, and partial overheating of the semiconductor element 6a can be suppressed.

Further, as illustrated in FIG. 7, even in a case where the horizontal portion 72c which is a part of the coupling portion 72 is formed in the crank shape in a planar view, the position of the center of gravity can be brought close to a central part of the horizontal portion 72c in a planar view. As a result, shape variations of the metal wiring board 7 can be sufficiently ensured.

In addition, as described above, the recesses 70b are formed by recessing the first joining portion 70 of the metal wiring board 7 from the upper surface side, and the bosses 70a are formed to protrude from the lower surface side. The bosses 70a are arranged at positions close to four corners of the rectangular first joining portion 70 in a planar view. By forming the plurality of bosses 70a as described above, the first joining portion 70 is not inclined with respect to the upper surface of the semiconductor element 6a in a joining step of the metal wiring board 7. Thus, the posture of the metal wiring board 7 (the first joining portion 70) can be stabilized.

In addition, by providing the bosses 70a on the lower surface of the metal wiring board 7, a gap can be secured by at least a height of the boss 70a between the first joining portion 70 and the semiconductor element 6a. By filling the gap with the joining material S, a thickness of the joining material S can be secured. Consequently, sufficient joining strength can also be ensured.

In addition, the recesses 70b are formed at positions corresponding to positions immediately above the bosses 70a, in the upper surface of the first joining portion 70. As a result, a surface area of the upper surface of the first joining portion 70 increases, and the adhesion (anchor effect) between the upper surface of the first joining portion 70 and the sealing resin 4 can be improved. Hence, the progress of the peeling of the upper surface of the metal wiring board 7 due to thermal stress can be suppressed at a position above the semiconductor element 6a.

In addition, the bosses 71a protruding downward are also formed on a back surface side of the second joining portion 71. Consequently, a gap can be secured by at least a height of the boss 71a between the second joining portion 71 and the facing circuit board 53. By filling the gap with the joining material S, a thickness of the joining material S can be secured.

Hereinafter, the metal wiring board 9 on the lower arm side will be described below. The metal wiring board 9 on the lower arm side basically has a configuration common to that of the metal wiring board 7 on the upper arm side and differs from the metal wiring board 7 in that orientations of some configurations are different.

As illustrated in FIGS. 3, 9, and 10, the metal wiring board 9 includes the third joining portion 90, the fourth joining portion 91, and the coupling portion 92. The coupling portion 92 further has a third rising portion 92a, a fourth rising portion 92b, and a horizontal portion 92c.

The third joining portion 90 is formed in a rectangular shape smaller than the main electrode 60b of the semiconductor element 6b in a planar view. For example, the third joining portion 90 has a rectangular shape with long sides in the Y direction and short sides in the X direction. The third joining portion 90 includes a plate-shaped part having an upper surface and a lower surface in an XY plane and having a thickness in the Z direction. The third joining portion 90 is joined to a widthwise center of one side of the main electrode 60b in the Y direction on the upper surface side. That is, the side of the third joining portion 90 in the Y direction is formed to include a center line of the main electrode 60b in the X direction on the upper surface side. More preferably, a center line Cy of the third joining portion 90 in the Y direction is set within a range of 10% or smaller of a length of the main electrode 60b in the Y direction from the center line of the main electrode 60b in the Y direction on the upper surface side. Still more preferably, the center line of the main electrode 60b in the X direction on the upper surface side coincides with the center line Cy of the third joining portion 90 in the Y direction. In addition, the third joining portion 90 is joined to a widthwise center of one side of the main electrode 60b in the X direction on the upper surface side.

That is, the side of the third joining portion 90 in the X direction is formed to include the center line of the main electrode 60b in the X direction on the upper surface side. More preferably, a center line C1 of the third joining portion 90 in the X direction is set within a range of 10% or smaller of a length of the main electrode 60b in the X direction from the center line of the main electrode 60b in the X direction on the upper surface side. Still more preferably, the center line of the main electrode 60b in the X direction on the upper surface side coincides with the center line C1 of the third joining portion 90 in the X direction.

In addition, a plurality of (four in the present embodiment) bosses 90a protruding downward are formed on the lower surface of the third joining portion 90. The bosses 90a are arranged at respective positions corresponding to four corners of the third joining portion 90. In addition, recesses 90b are formed at positions corresponding to the positions immediately above the bosses 90a, in the upper surface of the third joining portion 90. The third joining portion 90 is disposed to face the upper surface electrode (main electrode 60b) of the semiconductor element 6 in the Z direction and is joined thereto via the joining material S.

In addition, the upper surface of the third joining portion 90 may have a roughened surface having a surface roughness larger than that of other parts. The roughened surface can be formed by intentionally exposing the surface to, for example, a solvent, a laser, a die, or the like. According to this roughened surface, adhesion to a resin is improved as an anchor effect.

For example, as illustrated in FIG. 9, the fourth joining portion 91 is formed in a rectangular shape with short sides in the Y direction and long sides in the X direction in a planar view. The fourth joining portion 91 includes a plate-shaped part having an upper surface and a lower surface in an XY plane and having a thickness in the Z direction.

In addition, a plurality of (two in the present embodiment) bosses 91a protruding downward are formed on the lower surface of the fourth joining portion 91. The two bosses 91a are arranged side by side in a longitudinal direction of the fourth joining portion 91. In addition, recesses 91b are formed at positions corresponding to positions immediately above the bosses 91a, in the upper surface of the fourth joining portion 91. The fourth joining portion 91 is disposed to face the upper surface of the circuit board 54 in the Z direction and is joined thereto via the joining material S.

The third joining portion 90 and the fourth joining portion 91 are arranged to partially face each other in the Y direction in a planar view. That is, one side of the third joining portion 90 and one side of the fourth joining portion 91 are arranged in parallel at a predetermined distance. Further, the one side of the third joining portion 90 and the one side of the fourth joining portion 91 are arranged to obliquely face each other in a planar view. For example, as illustrated in FIG. 9, a long side of the third joining portion 90 and a long side of the fourth joining portion 91 are arranged in parallel at a predetermined distance and partially face each other.

The coupling portion 92 (second coupling portion) couples the third joining portion 90 and the fourth joining portion 91 described above together. The coupling portion 92 includes a plate-shaped part formed in a gate shape or an arch shape in a side view. Specifically, the coupling portion 92 includes a third rising portion 92a rising upward from the one side of the third joining portion 90, a fourth rising portion 92b rising upward from the one side of the fourth joining portion 91, and a horizontal portion 92c coupling an upper end of the third rising portion 92a and an upper end of the fourth rising portion 92b together. The third rising portion 92a constitutes one end part of the coupling portion 92, and the fourth rising portion 92b constitutes the other end part of the coupling portion 92.

The third rising portion 92a rises perpendicularly with respect to the third joining portion 90 from the one side (for example, the one side facing the fourth joining portion 91) of the third joining portion 90. The third rising portion 92a includes a plate-shaped part having a main surface on a ZX plane parallel to the one side of the third joining portion 90, a side surface on a YZ plane, a width in the X direction, and a thickness in the Y direction (see FIGS. 9 and 10). The width of the third rising portion 92a is smaller than a width of the connected third joining portion 90 (a length of the one side of the third joining portion 90). The thickness of the third rising portion 92a may be substantially the same as a thickness of the third joining portion 90. For example, the thickness of the third rising portion 92a may be 80% or larger and 120% or smaller of the thickness of the third joining portion 90.

In addition, the third rising portion 92a is coupled to a widthwise center of the one side of the third joining portion 90. That is, the third rising portion 92a is formed to include the widthwise center of the one side of the third joining portion 90. More preferably, a widthwise center line C2 of the third rising portion 92a is set within a range of 10% or smaller of the width of the one side of the third joining portion 90 from the widthwise center line C1 of the one side of the third joining portion 90. More preferably, as illustrated in FIG. 9, the widthwise center line C2 of the third rising portion 92a coincides with the widthwise center line C1 of the one side of the third joining portion 90. In FIG. 9, the center lines C1 and C2 are slightly shifted from each other in the Y direction for convenience of illustration. That is, in the present embodiment, it is not excluded that the center lines C1 and C2 completely coincide with each other.

The fourth rising portion 92b rises perpendicularly with respect to the fourth joining portion 91 from the one side (for example, the one side facing the third joining portion 90) of the fourth joining portion 91. The fourth rising portion 92b includes a plate-shaped part having a main surface on a ZX plane parallel to the one side of the fourth joining portion 91, a side surface on a YZ plane, a width in the X direction, and a thickness in the Y direction (see FIGS. 9 and 10). The width of the fourth rising portion 92b is smaller than a width of the connected fourth joining portion 91 (a length of the one side of the fourth joining portion 91). The thickness of the fourth rising portion 92b may be substantially the same as a thickness of the fourth joining portion 91. For example, the thickness of the fourth rising portion 92b may be 80% or larger and 120% or smaller of the thickness of the fourth joining portion 91.

In addition, the fourth rising portion 92b is coupled to the widthwise center of the one side of the fourth joining portion 91. That is, the fourth rising portion 92b is formed to include the widthwise center of the one side of the fourth joining portion 91. More preferably, a widthwise center line C4 of the fourth rising portion 92b is set within a range of 10% or smaller of the width of the one side of the fourth joining portion 91 from a widthwise center line C3 of the one side of the fourth joining portion 91. More preferably, as illustrated in FIG. 9, the widthwise center line C4 of the fourth rising portion 92b coincides with the widthwise center line C3 of the one side of the fourth joining portion 91. In FIG. 9, the center lines C3 and C4 are slightly shifted from each other in the Y direction for convenience of illustration. That is, in the present embodiment, it is not excluded that the center lines C3 and C4 completely coincide with each other.

The third rising portion 92a and the fourth rising portion 92b are arranged to partially face each other in the Y direction in a planar view. That is, one surface of the third rising portion 92a and one surface of the fourth rising portion 92b are arranged in parallel at a predetermined distance. Further, the one surface of the third rising portion 92a and the one surface of the fourth rising portion 92b are arranged to obliquely face each other in a planar view. For example, as illustrated in FIG. 9, the one surface of the third rising portion 92a and the one surface of the fourth rising portion 92b are arranged in parallel at the predetermined distance and partially face each other. In addition, the thickness of the third rising portion 92a and the thickness of the fourth rising portion 92b are preferably the same.

In addition, a height of the upper end of the third rising portion 92a and a height of the upper end of the fourth rising portion 92b are preferably the same. On the other hand, a lower end of the third rising portion 92a is positioned to be preferably higher than a lower end of the fourth rising portion 92b. That is, the third joining portion 90 is provided at a position (position on the positive side in the Z direction) higher than the fourth joining portion 91. More specifically, the third joining portion 90 is preferably provided at a position higher than the fourth joining portion 91 by the thickness of the semiconductor element 6b.

The horizontal portion 92c includes a plate-shaped part having an upper surface and a lower surface in an XY plane and having a thickness in the Z direction. In addition, the horizontal portion 92c has a crank shape bent twice at a substantially right angle in a planar view. A width of the horizontal portion 92c is preferably the same as that of the third rising portion 92a or the fourth rising portion 92b.

More specifically, as illustrated in FIG. 9, the horizontal portion 92c includes a first extending portion 92d, a second extending portion 92e, and a third extending portion 92f. The first extending portion 92d has a rectangular shape extending in the Y direction with a predetermined width from the one side of the third joining portion 90 facing the fourth joining portion 91. The first extending portion 92d is long in the X direction. The second extending portion 92e is continuous to one side of the first extending portion 92d and has a rectangular shape extending in the X direction with a predetermined width. The second extending portion 92e is long in the X direction. The third extending portion 92f has a rectangular shape extending in the Y direction with a predetermined width from the one side of the fourth joining portion 91 facing the third joining portion 90. The third extending portion 92f is long in the X direction. The third extending portion 92f is continuous to one side of the second extending portion 92e. In addition, in the horizontal portion 92c (second extending portion 92e), the first extending portions 92d (fillets) are formed at edge parts (two diagonally facing corner portions), respectively, in a planar view.

The thickness of the metal wiring board 9 configured as described above is a uniform thickness from the third joining portion 90 to the fourth joining portion 91, but is not limited thereto. For example, the thickness of the metal wiring board 9 is not necessarily uniform from the third joining portion 90 to the fourth joining portion 91 and may be partially thin.

In the present embodiment, one end of the coupling portion 92 is coupled to the widthwise center of the one side of the third joining portion 90, and the other end of the coupling portion 92 is coupled to the widthwise center of the one side of the fourth joining portion 91. Consequently, the position of the center of gravity of the metal wiring board 9 alone is positioned near the center of the coupling portion 92 (horizontal portion 92c). Hence, the self-standing stability of the metal wiring board 9 alone can be improved, and it is possible to prevent inclination and the like of the joining portion by suppressing a posture change at the time of joining as much as possible.

The coupling is also performed on a widthwise center of the upper surface electrode (main electrode 60b) of the semiconductor element 6b. Therefore, a current bias in the width direction (Y direction) in the upper surface electrode (main electrode 60b) can be suppressed, and partial overheating of the semiconductor element 6b can be suppressed.

Further, as illustrated in FIG. 9, even in a case where the horizontal portion 92c which is a part of the coupling portion 92 is formed in the crank shape in a planar view, the position of the center of gravity can be brought close to a central part of the horizontal portion 92c in a planar view. As a result, shape variations of the metal wiring board 9 can be sufficiently ensured.

In addition, as described above, the recesses 90b are formed by recessing the third joining portion 90 of the metal wiring board 9 from the upper surface side, and the bosses 90a are formed to protrude from the lower surface side. The bosses 90a are arranged at positions close to four corners of the rectangular third joining portion 90 in a planar view. By forming the plurality of bosses 90a as described above, the third joining portion 90 is not inclined with respect to the upper surface of the semiconductor element 6b in a joining step of the metal wiring board 9. Thus, the posture of the metal wiring board 9 (the third joining portion 90) can be stabilized.

In addition, by providing the bosses 90a on the lower surface of the metal wiring board 9, a gap can be secured by at least a height of the boss 90a between the third joining portion 90 and the semiconductor element 6b. By filling the gap with the joining material S, a thickness of the joining material S can be secured. Consequently, sufficient joining strength can also be ensured.

In addition, the recesses 90b are formed at positions corresponding to positions immediately above the bosses 90a, in the upper surface of the third joining portion 90. As a result, a surface area of the upper surface of the third joining portion 90 increases, and the adhesion (anchor effect) between the upper surface of the third joining portion 90 and the sealing resin 4 can be improved. Hence, the progress of the peeling of the upper surface of the metal wiring board 9 due to thermal stress can be suppressed at a position above the semiconductor element 6b.

In addition, the bosses 91a protruding downward are also formed on a back surface side of the fourth joining portion 91. Consequently, a gap can be secured by at least a height of the boss 91a between the fourth joining portion 91 and the facing circuit board 54. By filling the gap with the joining material S, a thickness of the joining material S can be secured.

According to the metal wiring boards 7 and 9, it is possible to stabilize the position of the center of gravity when the metal wiring boards 7 and 9 are arranged. As illustrated in FIGS. 7 and 9, widths of predetermined portions constituting the metal wiring boards 7, 9 are denoted by D1, D2, and D3, respectively.

Here, by increasing D2 while maintaining a relationship of D1>D2 and D3>D2, areas of the coupling portions 72 and 92 are increased, and the stability of the center of gravity is improved. In addition, by increasing D3 within a range that does not affect structural dimensions and manufacturing dimensions of other components, a contact surface with a circuit board can be increased, and the stability is further improved. In addition, by increasing D3, in addition to stabilizing the center of gravity, the coupling portions 72 and 92 can efficiently dissipate heat downward from the laminate substrate 5.

In addition, by increasing D2, output characteristics can be further improved. In a case where the same current flows, cross-sectional areas of the coupling portions 72 and 92 can be increased in a case where D2 is increased, and heat generation can be reduced, that is, an allowable current can be increased. In addition, by increasing D2 while the lengths of metal wiring boards 7 and 9 are maintained, a cross-sectional area of the current path can be increased, and the inductance can be reduced. That is, D2 can be increased within a range in which a reliability tolerance is not affected.

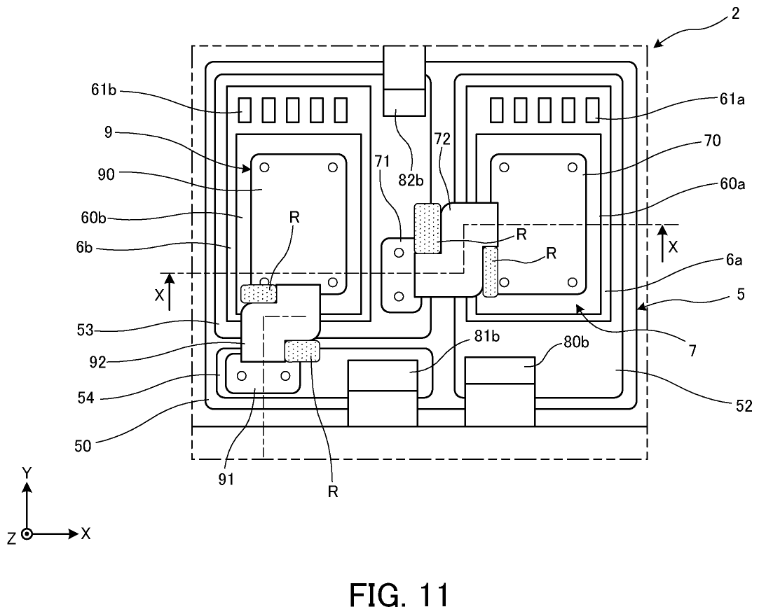

Further, in addition to the above-described effects, the following effects can also be expected. FIG. 11 is a plan view focusing on the periphery of the metal wiring board in FIG. 3.

In the semiconductor module 1, in order to improve the adhesion between the semiconductor units 2 and the case 3 and the sealing resin 4, a coating layer is applied to an internal member to improve adhesion with the resin. The coating layer may include at least one of polyimide or polyamide. The coating layer is applied by, for example, a spray method.

In the present embodiment, by forming the coupling portions 72 and 92 of the metal wiring boards 7 and 9 in the crank shape, an area of the coupling portion (horizontal portion) can be reduced. Consequently, this makes it possible to appropriately apply the coating layer to a component (the laminate substrate 5 or the semiconductor element 6a or 6b) positioned immediately below the metal wiring boards 7 and 9. Specifically, the coating layer can also be appropriately applied to a region R in FIG. 11. The region R is a rectangular region positioned in the vicinity of a corner (fillet) of the crank shape of the horizontal portion. Since the vicinity of the fillet is a position where resin peeling is likely to occur, the coating layer is also applied to the region R, so that the coating layer is easily applied to the surfaces of the laminate substrate 5 or the semiconductor elements 6a and 6b around the metal wiring boards 7 and 9. Consequently, adhesion between the sealing resin 4 and peripheral members thereof is improved, and insulation and reliability resistance can be improved.

Next, a layout around the metal wiring boards 7 and 9 will be described. As illustrated in FIGS. 3 and 7 to 10, the circuit boards 52 and 53 are arranged side by side in the X direction. In addition, the circuit boards 53 and 54 are arranged side by side in the Y direction intersecting the X direction.

In addition, the P terminal 80 and the N terminal 81 are arranged side by side in the X direction. The M terminal 82 is disposed to face the N terminal 81 across the circuit boards 53 and 54. More specifically, the M terminal 82 is disposed to face the N terminal 81 across the second joining portion 71 on the upper arm side.

As described above, the first joining portion 70 and the second joining portion 71 on the upper arm side are arranged such that the one side of the first joining portion 70 and the one side of the second joining portion 71 face each other in a planar view. In addition, the coupling portion 72 on the upper arm side couples the one side of the first joining portion 70 and the one side of the second joining portion 71 facing each other.

As described above, by coupling the facing sides by the coupling portion 72, the main current path between the semiconductor element 6 on the upper arm side and the circuit board 53 can be further shortened as illustrated in FIGS. 3 and 7.

Similarly, the first joining portion 70 and the second joining portion 71 on the lower arm side are arranged such that the sides thereof on one side face each other in a planar view. In addition, the coupling portion 72 on the lower arm side couples the one side of the first joining portion 70 and the one side of the second joining portion 71 facing each other.

As described above, also on the lower arm side, the main current path between the semiconductor element 6 and the circuit board 54 can be further shortened by coupling the facing sides by the coupling portion 72. Consequently, the inductance of the entire module can be reduced.

Further, the horizontal portion 72c has the crank shape in a planar view for both the upper and lower arms, and thereby it is possible to adjust the main current path in a state where the position of the center of gravity is maintained at a stable position according to the shape and layout of the peripheral main terminals (the P terminal 80, the N terminal 81, and the M terminal 82) and the circuit boards 52 to 54. As a result, it is possible to increase product variations according to the layout. For example, it is preferable that the semiconductor element 6a and the metal wiring board 7 on the upper arm side be arranged close to the P terminal 80 side (negative side in the Y direction) and the fourth joining portion 91 of the metal wiring board 9 on the lower arm side be disposed close to the N terminal 81.

As described above, according to the present embodiment, the center of gravity of the metal wiring board 7 can be stabilized, stress concentration on an interface with respect to the metal wiring board after sealing can be prevented, and the main current path can be prevented from being close to one side. In addition, an inductance reduction effect can be obtained by shortening the main current path. Further, it is easy to adjust the layout of various components in the module, and it is easy to change a chip size and change the design of the components according to product variations.

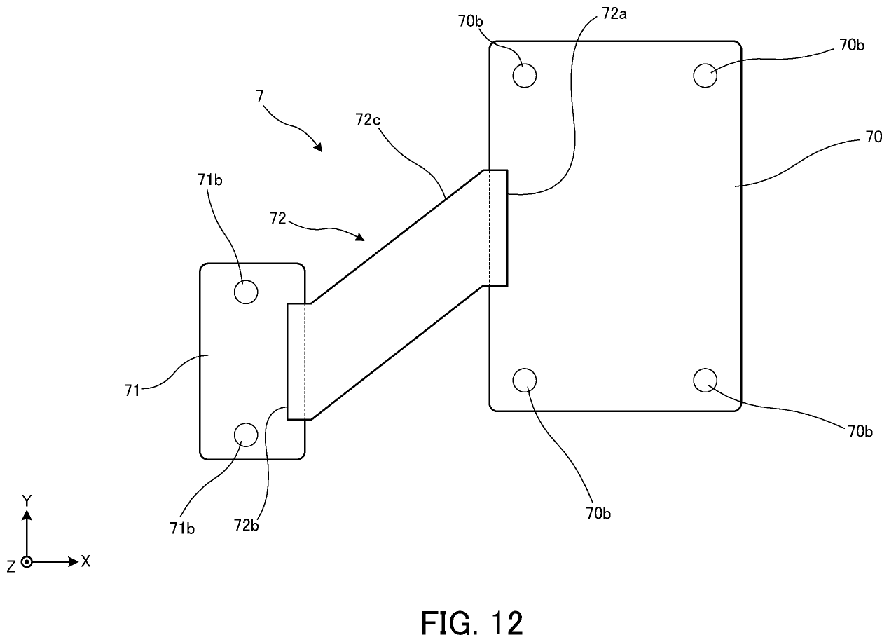

In the above-described embodiment, the case where the metal wiring board (coupling portion) has the crank shape in a planar view has been described; however, the present invention is not limited to this configuration. For example, configurations illustrated in FIG. 12 can also be employed. FIG. 12 is a plan view of a metal wiring board according to a modification example. In FIG. 12, a metal wiring board 7 will be described as an example, but the same shape can also be applied to a metal wiring board 9. As illustrated in FIG. 12, in the metal wiring board 7 according to the modification example, a coupling portion 72 (horizontal portion 72c) is formed of an elongated body extending obliquely in a planar view. According to this configuration, since the wiring path can be further shortened by linearly forming the horizontal portion 72c, it is possible to obtain an effect of further reducing the inductance.

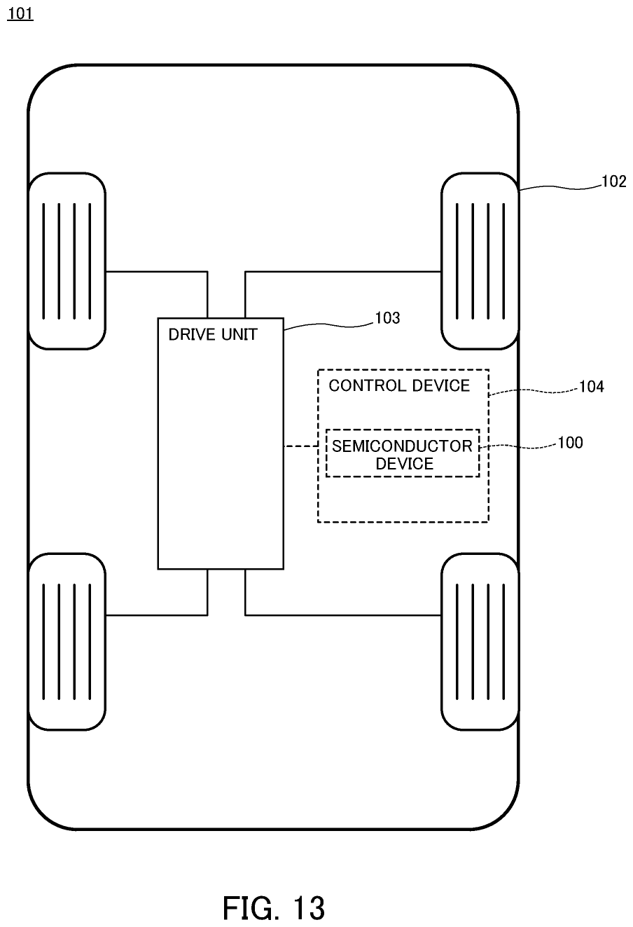

A vehicle to which the present invention is applied will be described with reference to FIG. 13. FIG. 13 is a schematic plan view illustrating an example of the vehicle to which the semiconductor device according to the present invention is applied. A vehicle 101 illustrated in FIG. 13 includes, for example, a four-wheeled vehicle including four wheels 102. The vehicle 101 may be, for example, an electric vehicle that drives wheels by a motor or the like, or a hybrid vehicle using power of an internal combustion engine in addition to the motor.

The vehicle 101 includes a drive unit 103 which applies power to the wheels 102 and a control device 104 which controls the drive unit 103. The drive unit 103 may include, for example, at least one of an engine, the motor, and a hybrid of the engine and the motor.

The control device 104 performs control (for example, power control) of the drive unit 103 described above. The control device 104 includes the semiconductor device 100 described above. The semiconductor device 100 may be configured to perform power control on the drive unit 103.

In the above-described embodiment, the number and the arrangement positions of the semiconductor elements 6a and 6b are not limited to the above-described configuration and can be appropriately changed.

In addition, in the above-described embodiment, the number and the layout of the wiring boards are not limited to the above-described configuration and can be appropriately change.

In the above-described embodiment, the laminate substrate 5 and the semiconductor elements 6a and 6b are each configured to have a rectangular shape or a square shape in a planar view, but the present invention is not limited to this configuration. These components may each have a polygonal shape other than the above-described shape.

The present embodiment and the modification examples have been described, and the above-described embodiment and modification examples may be wholly or partially combined as another embodiment.

In addition, the present embodiment is not limited to the above-described embodiment and modification examples, and various changes, substitutions, and modifications may be made without departing from the spirit of the technical idea. Further, when the technical idea can be realized in another manner by the progress of the technology or another derived technology, the technical idea may be carried out by using a method thereof. Hence, the claims cover all embodiments that may be included within the scope of the technical idea.

Feature points in the embodiment described above will be summarized below.

A semiconductor module according to the embodiment includes: a first circuit board to which one end of a P terminal is electrically connected; a second circuit board to which one end of an M terminal is electrically connected; a third circuit board to which one end of an N terminal is electrically connected; a first semiconductor element disposed on an upper surface of the first circuit board; a second semiconductor element disposed on an upper surface of the second circuit board; a first metal wiring board configured to connect the first semiconductor element and the second circuit board; and a second metal wiring board configured to connect the second semiconductor element and the third circuit board. The first metal wiring board includes a first joining portion having a rectangular shape in a planar view and joined to an upper surface of a main electrode on an upper surface side of the first semiconductor element, a second joining portion having a rectangular shape in a planar view and joined to an upper surface of the second circuit board, and a first coupling portion configured to couple the first joining portion and the second joining portion. The first joining portion and the second joining portion are arranged such that one side of the first joining portion and one side of the second joining portion face each other in a planar view. The first coupling portion couples the one side of the first joining portion and the one side of the second joining portion facing each other. The second metal wiring board includes a third joining portion having a rectangular shape in a planar view and joined to an upper surface of a main electrode on an upper surface side of the second semiconductor element, a fourth joining portion having a rectangular shape in a planar view and joined to an upper surface of the third circuit board, and a second coupling portion configured to couple the third joining portion and the fourth joining portion. The third joining portion and the fourth joining portion are arranged such that one side of the third joining portion and one side of the fourth joining portion face each other in a planar view. The second coupling portion couples the one side of the third joining portion and the one side of the fourth joining portion facing each other.

In addition, in the semiconductor module according to the above-described embodiment, the first circuit board and the second circuit board are arranged side by side in a predetermined direction, and the second circuit board and the third circuit board are arranged side by side in a direction intersecting the predetermined direction.

In addition, in the semiconductor module according to the above-described embodiment, the first coupling portion extends in the predetermined direction, and the second coupling portion extends in a direction intersecting the predetermined direction.

In addition, in the semiconductor module according to the above-described embodiment, each of the first semiconductor element and the second semiconductor element has a main electrode formed on each upper surface on one side in the direction intersecting the predetermined direction and a control electrode formed on the upper surface on the other side.

In addition, in the semiconductor module according to the above-described embodiment, in a planar view, the second metal wiring board extends from the upper surface of the second semiconductor element to one side in the direction intersecting the predetermined direction, and a control wiring extends to the other side in the direction intersecting the predetermined direction.

In addition, in the semiconductor module according to the above-described embodiment, a direction in which the one side of the first joining portion and the one side of the second joining portion face each other intersects a direction in which the one side of the third joining portion and the one side of the fourth joining portion face each other.

In addition, in the semiconductor module according to the above-described embodiment, the P terminal and the N terminal are arranged side by side in a predetermined direction, the M terminal is disposed to face the N terminal across the second joining portion, and a direction in which the M terminal faces the N terminal is a direction intersecting the predetermined direction.

In addition, in the semiconductor module according to the above-described embodiment, a control terminal is disposed on the M terminal side.

In addition, in the semiconductor module according to the above-described embodiment, one end of the first coupling portion is coupled to a widthwise center of one side of the first joining portion.

In addition, in the semiconductor module according to the above-described embodiment, the one side of the first joining portion and the one side of the second joining portion are arranged to obliquely face each other in a planar view, and the second coupling portion includes a plate-shaped part having a crank shape in a planar view.

In addition, in the semiconductor module according to the above-described embodiment, the crank shape of the first coupling portion is bent away (toward a negative side in a Y direction) from a joining portion between the M terminal and the second circuit board. According to this configuration, the joining portion on the M terminal side and the second joining portion can be arranged away from each other by a predetermined distance on the second circuit board (circuit board 53), and a thermal interference between the joining portions is reduced, so that the reliability of each joining portion can be enhanced.

In addition, in the semiconductor module according to the above-described embodiment, the first coupling portion includes a first rising portion rising upward from the one side of the first joining portion, a second rising portion rising upward from the one side of the second joining portion, and a horizontal portion configured to couple an upper end of the first rising portion and an upper end of the second rising portion and have a crank shape in a planar view.

In addition, in the semiconductor module according to the above-described embodiment, the horizontal portion has a fillet formed at an edge part of the horizontal portion in a planar view.

In addition, in the semiconductor module according to the above-described embodiment, the other end of the first coupling portion is coupled to a widthwise center of one side of the second joining portion.

In addition, in the semiconductor module according to the above-described embodiment, one end of the second coupling portion is coupled to a widthwise center of one side of the third joining portion.

In addition, in the semiconductor module according to the above-described embodiment, the one side of the third joining portion and the one side of the fourth joining portion are arranged to obliquely face each other in a planar view, and the second coupling portion includes a plate-shaped part having a crank shape in a planar view.

In addition, in the semiconductor module according to the above-described embodiment, the crank shape of the second coupling portion is bent away (toward a negative side in an X direction) from a joining portion between the N terminal and the third circuit board. According to this configuration, the joining portion on the N terminal side and the fourth joining portion can be arranged away from each other by a predetermined distance on the third circuit board (circuit board 54), and a thermal interference between the joining portions is reduced, so that the reliability of each joining portion can be enhanced.

In addition, the metal wiring board according to the above-described embodiment includes a first joining portion having a rectangular shape in a planar view and joined to an upper surface of a main electrode of the semiconductor element, a second joining portion having a rectangular shape in a planar view and joined to an upper surface of a predetermined circuit board, and a coupling portion configured to couple the first joining portion and the second joining portion. One side of the first joining portion and one side of the second joining portion are arranged to face each other. One end of the coupling portion is coupled to a widthwise center of the one side of the first joining portion.

In addition, in the metal wiring board according to the above-described embodiment, a widthwise center line of the one end of the coupling portion is set within a range of 10% or smaller of the width of the one side of the first joining portion from a widthwise center line of the one side of the first joining portion.

In addition, in the metal wiring board according to the above-described embodiment, the widthwise center line of the one end of the coupling portion coincides with the widthwise center line of the one side of the first joining portion.

In addition, in the metal wiring board according to the above embodiment, one side of the first joining portion and one side of the second joining portion are arranged to obliquely face each other in a planar view, and the coupling portion includes a plate-shaped part having a crank shape in a planar view.

In addition, in the metal wiring board according to the above-described embodiment, the coupling portion includes a first rising portion rising upward from the one side of the first joining portion, a second rising portion rising upward from the one side of the second joining portion, and a horizontal portion configured to couple an upper end of the first rising portion and an upper end of the second rising portion and have a crank shape in a planar view.

In addition, in the metal wiring board according to the above-described embodiment, the horizontal portion includes: a first extending portion extending from the one side of the first joining portion in a direction perpendicular to the one side, with a predetermined width, a second extending portion which is continuous to one side of the first extending portion and extends in a direction perpendicular to the first extending portion with a predetermined width, and a third extending portion which extends from one side of the second joining portion in a direction perpendicular to the one side, with a predetermined width, and is continuous to one side of the second extending portion.

In addition, in the metal wiring board according to the above-described embodiment, the horizontal portion has a fillet formed at an edge part of the horizontal portion in a planar view.

In addition, in the semiconductor module according to the above-described embodiment, the other end of the coupling portion is coupled to a widthwise center of the one side of the second joining portion.

In addition, in the metal wiring board according to the above-described embodiment, a widthwise center line of the other end of the coupling portion is set within a range of 10% or smaller of the width of the one side of the second joining portion from a widthwise center line of the one side of the second joining portion.

In addition, in the metal wiring board according to the above-described embodiment, the widthwise center line of the other end of the coupling portion coincides with the widthwise center line of the one side of the second joining portion.

In addition, in the metal wiring board according to the above-described embodiment, each of the first joining portion and the second joining portion includes a plate-shaped part having an upper surface and a lower surface and has bosses formed on the lower surface of the plate-shaped part and protruding downward and recesses formed at positions corresponding to positions immediately above the boss on the upper surface of the plate-shaped part

In addition, in the metal wiring board according to the above embodiment, the bosses are provided on one side and the other side in the width direction of the one side of the first joining portion in a planar view, and the center line of the one end of the coupling portion is disposed between the bosses. According to this configuration, the bosses are positioned on an outer side of the joining portion, and the metal wiring board can be stably disposed.

In addition, in the metal wiring board according to the above embodiment, the bosses are provided on one side and the other side in the width direction of the one side of the first joining portion in a planar view, and the one end of the coupling portion is entirely disposed between the bosses. According to this configuration, the bosses are positioned on an outer side of the joining portion, and the metal wiring board can be stably disposed.

In addition, in the metal wiring board according to the above embodiment, the bosses are provided on one side and the other side in the width direction of the one side of the second joining portion in a planar view, and the center line of the one end of the coupling portion is disposed between the bosses. According to this configuration, the bosses are positioned on an outer side of the joining portion, and the metal wiring board can be stably disposed.

In addition, in the metal wiring board according to the above embodiment, the bosses are provided on one side and the other side in the width direction of the one side of the second joining portion in a planar view, and the one end of the coupling portion is entirely disposed between the bosses. According to this configuration, the bosses are positioned on an outer side of the joining portion, and the metal wiring board can be stably disposed.

As described above, the present invention has an effect of enabling the inductance to be reduced by shortening a wiring path, and is particularly useful for a semiconductor module for electrical equipment.

The present application is based on Japanese Patent Application No. 2022-051039 filed on Mar. 28, 2022. All the contents are included herein.

What is claimed is:

1. A semiconductor module, comprising:
first, second and third terminals;
a first circuit board to which one end of the first terminal is electrically connected;
a second circuit board to which one end of the second terminal is electrically connected;
a third circuit board to which one end of the third terminal is electrically connected;
a first semiconductor element disposed on an upper board surface of the first circuit board having a first main electrode on an upper element surface of the first semiconductor element;
a second semiconductor element disposed on an upper board surface of the second circuit board having a second main electrode on an upper element surface of the second semiconductor element; a first metal wiring board connecting the first semiconductor element to the second circuit board; and
a second metal wiring board connecting the second semiconductor element to the third circuit board, wherein
the first metal wiring board includes
a first joining portion having a rectangular shape in a plan view of the semiconductor module and being joined to an upper electrode surface of the first main electrode,
a second joining portion having a rectangular shape in the plan view and being joined to the upper board surface of the second circuit board, and
a first coupling portion configured to couple one side of the first joining portion to one side of the second joining portionsuch that the one side of the first joining portion and the one side of the second joining portion face each other in the plan view, the second metal wiring board includes
a third joining portion having a rectangular shape in the plan view and being joined to an upper electrode surface of the second main electrode,
a fourth joining portion having a rectangular shape in the plan view and being joined to the upper board surface of the third circuit board, and
a second coupling portion configured to couple one side of the third joining portion to one side of the fourth joining portion such that the one side of the third joining portion and the one side of the fourth joining portion face each other in the plan view.

2. The semiconductor module according to claim 1, wherein the first circuit board and the second circuit board face each other in a first direction, and
the second circuit board and the third circuit board face each other in a second direction intersecting the first direction.

3. The semiconductor module according to claim 1, wherein the first coupling portion extends in a first direction, and the second coupling portion extends in a second direction intersecting the first direction.

4. The semiconductor module according to claim 2, wherein
the first semiconductor element further includes a first control electrode, and the first main electrode and the first control electrode are disposed on the upper element surface of the first semiconductor element at one side and the other side opposite to each other in the second direction, and
the second semiconductor element further include a second control electrode and the second main electrode and the second control electrode are disposed on the upper electrode surface of the second semiconductor element at one side and the other side opposite to each other in the second direction.

5. The semiconductor module according to claim 2, further comprising a control wiring, wherein
in the plan view, from the upper element surface of the second semiconductor element,
the second metal wiring board extends in the second direction toward one side of the second semiconductor element, and
the control wiring extends in the second direction toward the another side opposite to the one side of the second semiconductor element.

6. The semiconductor module according to claim 1, wherein a first direction, in which the one side of the first joining portion and the one side of the second joining portion face each other, intersects a second direction in which the one side of the third joining portion and the one side of the fourth joining portion face each other.

7. The semiconductor module according to claim 1, wherein
the first terminal and the third terminal face each other in a first direction,
the second terminal is disposed to face the third terminal across the second circuit board, and
a direction in which the second terminal faces the third terminal is a second direction intersecting the first direction.

8. The semiconductor module according to claim 7, further comprising a plurality of control terminals disposed closer to the second terminal than are the first and third terminals and being respectively connected to respective ones of control electrodes of the first and second semiconductor elements.

9. The semiconductor module according to claim 1, wherein the first coupling portion is, at one end thereof, coupled to the one side of the first joining portion at a center thereof in a direction parallel to the one side of the first joining portion.

10. The semiconductor module according to claim 1, wherein
one side of the first joining portion and one side of the second joining portion are arranged to obliquely face each other in the plan view, and
the first coupling portion includes a plate-shaped part having a plurality of bends in different directions to form a shape of a crank in the plan view.

11. The semiconductor module according to claim 10, wherein one of the different directions is a direction away from a joining point between the second terminal and the second circuit board.

12. The semiconductor module according to claim 1, wherein
the first coupling portion includes
a first rising portion rising upward from the one side of the first joining portion,
a second rising portion rising upward from the one side of the second joining portion, and
a horizontal portion having two bends in different directions to form a shape of a crank in the plan view so as to couple an upper end of the first rising portion and an upper end of the second rising portion.

13. The semiconductor module according to claim 12, wherein the horizontal portion has a fillet to have a rounded corner at each of the two bends of the horizontal portion in the plan view.

14. The semiconductor module according to claim 9, wherein the first coupling portion is at another end thereof, coupled to the one side of the second joining portion at a center thereof in a direction parallel to the one side of the second joining portion.

15. The semiconductor module according to claim 1, wherein the second coupling portion is, at one end thereof, coupled to the one side of the third joining portion at a center thereof in a direction parallel to the one side of the third joining portion.

16. The semiconductor module according to claim 1, wherein
the one side of the third joining portion and the one side of the fourth joining portion are arranged to obliquely face each other in the plan view, and
the second coupling portion includes a plate-shaped part having a plurality of bends in different directions to have a shape of a crank in the plan view.

17. The semiconductor module according to claim 16, wherein one of the different directions is a direction away from a joining point between the third terminal and the third circuit board.
